(19) United States
(12) Patent Application Publication
(10) Pub. No.: US 2013/0043452 A1
(43) Pub. Date: Feb. 21, 2013

(54) Structures And Methods For Facilitating Enhanced Cycling Endurance Of Memory Accesses To Re-Writable Non Volatile Two Terminal Memory Elements

(71) Applicants: Rene Meyer, Atherton, CA (US); Jian Wu, San Jose, CA (US); Julie Casperson Brewer, Santa Clara, CA (US)

(72) Inventors: Rene Meyer, Atherton, CA (US); Jian Wu, San Jose, CA (US); Julie Casperson Brewer, Santa Clara, CA (US)

(73) Assignee: UNITY SEMICONDUCTOR CORPORATION, SUNNYVALE, CA (US)

(21) Appl. No.: 13/210,342

(22) Filed: Aug. 15, 2011

(51) Int. Cl. H01L 45/00; H01L 21/8239

(52) U.S. Cl. 257/4; 438/382; 257/E45.001; 257/E21.645; 257/E21.004

(57) ABSTRACT

Structures and methods to enhance cycling endurance of BEOL memory elements are disclosed. In some embodiments, a memory element can include a support layer having a smooth and planar upper surface as deposited or as created by additional processing. A first electrode is formed the smooth and planar upper surface. The support layer can be configured to influence the formation of the first electrode to determine a substantially smooth surface of the first electrode. The memory element is formed over the first electrode having the substantially smooth surface, the memory element including one or more layers of an insulating metal oxide (IMO) operative to exchange ions to store a plurality of resistive states. The substantially smooth surface of the first electrode provides for uniform current densities through unit cross-sectional areas of the IMO. The memory element can include one or more layers of a conductive metal oxide (CMO).

### CROSS-REFERENCE TO RELATED APPLICATIONS

This application is related to: pending U.S. patent application Ser. No. 12/661,678, filed on Mar. 22, 2010, and titled “Immersion Platinum Plating Solution”; pending U.S. patent application Ser. No. 12/454,322, filed on May 15, 2009, now U.S. Published Application No. 2010/0159688, and titled “Device Fabrication”; pending U.S. patent application Ser. No. 11/095,026, filed Mar. 30, 2005, and published as U.S. Pub. No. 2006/0171200, and titled “Memory Using Mixed Valence Conductive Oxides”; pending U.S. patent application Ser. No. 12/653,836, filed Dec. 18, 2009, and published as U.S. Pub. No. 2010/0157658, and titled “Conductive Metal Oxide Structures In Non-Volatile Re-Writable Memory Devices”; U.S. Pat. No. 7,897,951, issued on Mar. 1, 2011, and titled “Continuous Plane Of Thin-Film Materials For A Two-Terminal Cross-Point Memory”; pending U.S. patent application Ser. No. 12/653,851, filed Dec. 18, 2009, and published as U.S. Pub. No. 2010/0159641, and titled “Memory Cell Formation Using Ion Implant Isolated Conductive Metal Oxide”; pending U.S. patent application Ser. No. 13/171,350, Filed Jun. 28, 2011, and titled “Multilayer Cross-Point Memory Array Having Reduced Disturb Susceptibility”; U.S. Pat. No. 7,995,371, issued on Aug. 9, 2011, and titled “Threshold Device For A Memory Array”; and U.S. Pat. No. 7,884,349, issued on Feb. 8, 2011, and titled “Selection Device for Re-Writable Memory”, all of which are hereby incorporated by reference in their entirety for all purposes.

### FIELD OF THE INVENTION

Embodiments of the invention relate generally to semiconductors and memory technology, and more particularly, to systems, integrated circuits, and methods to enhance cycling endurance of memory elements, such as implemented in third dimensional memory technology.

### BACKGROUND

Conventional memory architectures and technologies, such as those including dynamic random access memory (“DRAM”) cells and Flash memory cells, typically are not well-suited to resolve issues of manufacturing and operating resistance change-based memory cells. The above-described memory architectures, while functional for their specific technologies, fall short of being able to adequately address the issues of cycling endurance of resistance-based memory elements and the degradation due to repeated write-erase cycles. As the structures of conventional memory cells differ from resistance-based memory elements, there are different requirements and approaches to improve the reliability (e.g., cycling endurance) of resistance-based memory elements.

It would be desirable to provide improved systems, integrated circuits, and methods that minimize one or more of the drawbacks associated with conventional techniques for facilitating improved cycling endurance for resistance-based memory elements disposed in, for example, cross-point arrays.

### BRIEF DESCRIPTION OF THE DRAWINGS

The invention and its various embodiments are more fully appreciated in connection with the following detailed description taken in conjunction with the accompanying drawings, in which:

FIG. 1 depicts a memory cell in accordance with various embodiments;

FIG. 2A depicts a portion of a conventional memory element structure in which a bottom electrode is not formed on top of a support layer and resulting surface roughness in a layer of memory material deposited on a rough surface of the bottom electrode;

FIGS. 2B and 2C depict electrode structures formed in relation to a support structure such as a support layer, according to various embodiments;

FIG. 3 depicts an example of a flow for forming a support layer, according to various embodiments;

FIG. 4 depicts an example of a memory cell and memory cells configured in a two-terminal cross-point array according to various embodiments;

FIG. 5 depicts an example of a flow to smoothen surfaces of structures in a memory cell, according to various embodiments;

FIG. 6A depicts an example of a flow to form a memory element, according to various embodiments;

FIG. 6B depicts another example of a flow to form a memory element, according to various embodiments;

FIG. 7A depicts a cross-sectional view of an exemplary memory cell formed between conductive array lines and having electrically conductive support layers in accordance with techniques described herein, according to one or more embodiments;

FIG. 7B depicts a cross-sectional view of another exemplary memory cell formed between conductive array lines and having a support layer that is not electrically conductive in accordance with techniques described herein, according to one or more embodiments;

FIG. 7C depicts a cross-sectional view of one example of a memory element formed on a support layer in accordance with various embodiments;

FIG. 7D depicts a cross-sectional view of another example of a memory element formed on a support layer in accordance with various embodiments;

FIG. 7E depicts a cross-sectional view of one example of a MIM NOD formed on a support layer in accordance with various embodiments;

FIG. 7F depicts a cross-sectional view of one example of a configuration for a memory element and a NOD and associated support layers in accordance with various embodiments;

FIG. 7G depicts a cross-sectional view of another example of a configuration for a memory element and a NOD and associated support layers in accordance with various embodiments;

FIG. 8 is a diagram depicting a perspective view on a portion of an integrated circuit that includes one or more layers of BEOL cross-point memory in accordance with various embodiments;

FIGS. 9A and 9B depict cross-sectional views of a integrated circuit that includes a single layer of memory and multiple layers of memory respectively, in accordance with various embodiments;

FIG. 10 depicts one example of a graphical representation of a non-linear I-V characteristic for a discrete memory element having integral selectivity;

FIGS. 11A and 11B are perspective drawings depicting a conductive metal oxide (CMO) based memory element including mobile oxygen ions which may be used to implement the memory elements of the memory arrays of the present invention, the drawing in FIG. 11A depicting an example of the CMO-based memory element in a low-resistance, erased state and the drawing in FIG. 11B depicting an example of the CMO-based memory element in a high-resistance, programmed state;

FIGS. 11C and 11D are perspective drawings depicting a CMO-based based memory element in an erased and programmed state respectively, during a read operation where a read voltage is applied across the terminals of the memory element to generate a read current; and

FIG. 11E depicts top plan views of a wafer processed FEOL to form a plurality of base layer die including active circuitry and an electrical interconnect structure and the same wafer subsequently processed BEOL to integrally form one layer or multiple layers of memory and their respective memory elements directly on top of the base layer die where the finished die can subsequently be singulated, tested, and packaged into integrated circuits.

Like reference numerals refer to corresponding parts throughout the several views of the drawings. Note that most of the reference numerals include one or two left-most digits that generally identify the figure that first introduces that reference number. Furthermore, the drawings are not necessarily to scale.

### DETAILED DESCRIPTION

Various embodiments or examples may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

In some examples, techniques such as those described herein enable emulation of multiple memory types for implementation on a single component such as a wafer, substrate, or die. U.S. patent application Ser. No. 11/095,026, filed Mar. 30, 2005, and published as U.S. Pub. No. 2006/0171200, and titled “Memory Using Mixed Valence Conductive Oxides,” already incorporated herein by reference in its entirety and for all purposes describes non-volatile third dimensional memory elements that may be arranged in a two-terminal, cross-point memory array. New memory structures are possible with the capability of this third dimensional memory array. The technology allows for the emulation of other memory technologies by duplicating the interface signals and protocols, while accessing the third dimensional memory array. The third dimensional memory array may emulate other types of memory (e.g., emulation of DRAM, SRAM, ROM, EEPROM, NAND Flash, and NOR Flash), providing memory combinations within a single component.

Non-volatile memories and memory materials may be fabricated using the described techniques to create a single-layer or multiple-layer three-terminal memory and a single-layer or multiple-layer two-terminal memory, such as a cross-point memory described in U.S. patent application Ser. No. 11/095,026 (incorporated above). Using materials including but not limited to silicon oxide (SiO₂), platinum (Pt), titanium nitride (TiN), yttria-stabilized zirconia (YSZ), tungsten (W), conductive metal oxide (CMO), conductive binary metal oxides, perovskites, manganites, and others, a memory may be formed with at least one layer of continuous memory material (e.g., an un-etched thin-film layer) sandwiched between two or more electrodes. As part of the formation of a memory cell, for example, a discrete bottom electrode of a memory cell may be formed by etching one or more layers of material. The etched layers may be filled with material and planarized. Above the bottom electrode, one or more layers of memory material may be deposited but not etched (i.e., continuous, un-etched layers of memory material). Above the un-etched layer(s) of memory material (e.g., the uppermost layer of continuous and un-etched memory material), additional layers of material, including a material for a top electrode, and optionally a non-ohmic device (“NOD”) may be deposited and etched to form an implantation mask that, when implanted using ion implantation techniques, creates an insulating layer of conductive metal oxide (“CMO”) (e.g., praseodymium calcium manganese oxide—PCMO) in regions of the CMO that are not covered by the implantation mask. The implantation mask may or may not include the NOD, that is, the NOD may be formed after the layers that comprise the implantation mask. The continuous and un-etched layer(s) of CMO may include perovskite-based structures and materials (e.g., PCMO) that, when exposed to argon (Ar), xenon (Xe), titanium (Ti), zirconium (Zr), aluminum (Al), silicon (Si), oxygen (O₂), silicon and oxygen, or other types of ion implantation techniques and materials, creates regions of CMO material that are electrically insulating. Depending on the type of CMO material selected, its thickness, and processing conditions, the insulating regions can have an amorphous structure that is electrically insulating or a crystalline structure that is electrically insulating. The described techniques enables the formation of memories with small feature sizes and matrices of top and bottom electrodes that are electrically insulated from one another with a greater degree of fabrication reliability and decreased defect or degradation rates. The described fabrication techniques may be varied and are not limited to the examples provided.

In some embodiments, an insulating metal oxide (IMO) structure, such as an electrolytic tunnel barrier, and one or more conductive oxide structures (e.g., one or more layers of a conductive oxide material and/or a mixed valence conductive oxide material) need not operate in a silicon substrate, and, therefore, can be fabricated above circuitry being used for other purposes. That is, the active circuitry portion can be fabricated front-end-of-the-line (“FEOL”) on a substrate (e.g., a Silicon (Si) wafer, die, or other semiconductor substrate) and one or more layers of two-terminal cross-point memory arrays that include the non-volatile memory elements can be fabricated back-end-of-the-line (“BEOL”) directly on top of the substrate and electrically coupled with the active circuitry in the FEOL layer using an inter-level interconnect structure also fabricated FEOL. Further, a two-terminal memory element can be arranged as a cross-point such that one terminal is electrically coupled with an X-direction line (or an “X-line”) and the other terminal is electrically coupled with a Y-direction line (or a “Y-line”). A third dimensional memory can include multiple memory elements vertically stacked upon one another, sometimes sharing X-direction and Y-direction lines in a layer of memory, and sometimes having isolated lines. When a first write voltage, VW1, is applied across the memory element (e.g., by applying ½ VW1 to the X-direction line and ½ −VW1 to the Y-direction line), the memory element can switch to a low resistive state. When a second write voltage, VW2, is applied across the memory element (e.g., by applying ½ VW2 to the X-direction line and ½ −VW2 to the Y-direction line), the memory element can switch to a high resistive state. Memory elements using electrolytic tunnel barriers and mixed valence conductive oxides can have VW1 opposite in polarity from VW2.

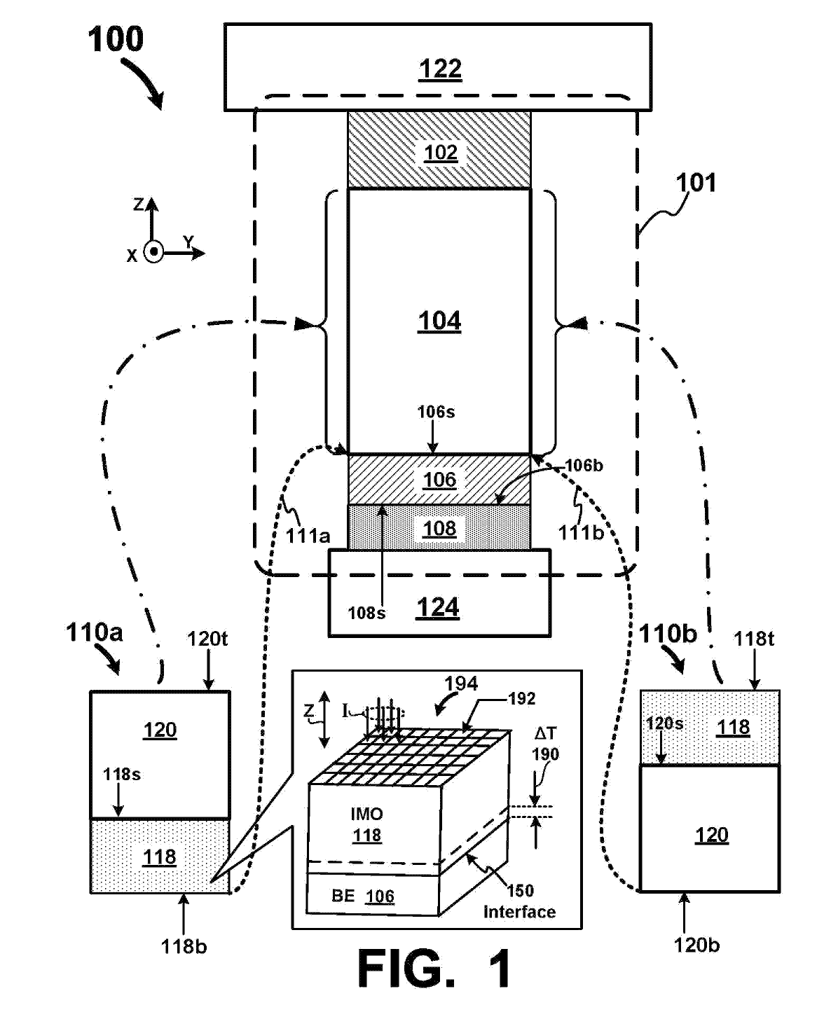

FIG. 1 depicts a configuration 100 that includes a memory cell in accordance with various embodiments. In configuration 100, a memory cell 101 includes a top electrode 102, a bottom electrode 106, a memory element 104 in contact with and electrically in series with the electrodes 102 and 106. Bottom electrode 106 is formed on a support structure denoted as a support layer 108 that includes a substantially planer and smooth upper surface 108s. Memory cell 101 can optionally include portions of array line 122 and array line 124 with array lines 122 and 124 operative to electrically couple the electrodes (e.g., terminals) of the memory element 104 with the array lines 122 and 124. The array lines 122 and 124 can be one of a plurality of conductive array lines in a cross-point array, such as a two-terminal cross-point array. Further, the array lines 122 and 124 can be oriented substantially orthogonal to each other with memory element 104 posited between a cross-point of array line 122 with array line 124. As such, memory cell 101 and memory element 104 can be a two-terminal memory structure. Memory element 104 is shown to include, but is not limited to, structures 110a and 110b. Memory element structure 110a includes a first substructure including at least one layer of an IMO material 118, upon which a second substructure including at least one layer of a CMO material 120 is formed. CMO material 120 can be a single layer of CMO or multiple layers of CMO and when multiple layers of CMO are implemented; the materials used for each CMO layer need not be the same material. Moreover, the different layers of CMO material can have thicknesses that vary among the CMO layers.

Memory element structure 110b includes a first substructure including at least one layer of a CMO material 120, upon which a second substructure including IMO material 118 is formed. As mentioned above, CMO material 120 can be a single layer of CMO or multiple layers of CMO and when multiple layers of CMO are implemented; the materials used for each CMO layer need not be the same material and the thicknesses of those materials can vary among the CMO layers.

Memory element 104 can include different and/or additional structures. As depicted by dashed line 111a, implementation of support layer 108 influences the structure and/or functionality of IMO material 118. Here, support layer 108 influences the structure of bottom electrode 106 upon which IMO 118 is deposited on the smooth upper surface 106s, the smooth upper surface 106s being influenced by smooth upper surface 108s of the support layer 108. In some embodiments, support layer 108 is configured to facilitate formation of IMO material 118 having a uniform thickness or a substantially uniform thickness. Support layer 108 also is configured to facilitate formation of smooth or a substantially smooth interface either between IMO material 118 and an electrode, such as bottom electrode 106, or between IMO material 118 and CMO material 120. For example, support layer 108 can facilitate formation of interface 150 between IMO material 118 and bottom electrode 106 that is sufficiently smooth to establish a relatively uniform thickness for IMO material 118. According to some embodiments, the smoothness of a surface, such as the surface of IMO material 118, is expressed in terms of values of “surface roughness,” whereby a value of surface roughness can represent a deviation 190 of the topology of the surface from an atomically smooth (e.g., planar) reference surface. In some examples, a measure of the surface roughness is the root mean square (RMS) deviation from a center line average over a roughness profiles (e.g., over a sufficient number of samples).

In view of the foregoing, the structures and/or functionalities of support layer 108 can facilitate formation of IMO material 118 having either a structure or a functionality, or both, that provides for enhanced cycling endurance, for example, over a number of data operation cycles, such as write cycles (e.g., program and erase), read cycles, and restore cycles, for example. With increased cycling endurance, the reliability of memory cell 101 and memory element 104 is thereby enhanced. According to some embodiments, support layer 108 is configured to facilitate formation of a relatively smooth interface 150 to influence the structure of bottom electrode 106. For example, support layer 108 can serve as a “template” (e.g., a growth template) to promote the formation of bottom electrode 106 in a manner that propagates the smoothness of an upper surface 108s of support layer 108 to an upper surface 106s of bottom electrode 106, thereby providing for a smooth surface 106s or a substantially smooth surface 106s of bottom electrode 106 to establish a relatively smooth interface 150 upon which to deposit a subsequent layer of material such as IMO 118 or CMO 120. Here, as material for bottom electrode 106 is deposited on the smooth upper surface 108s of the support layer 108, a bottom surface 106b of the electrode 106 is formed on the smooth foundation of the smooth upper surface 108s and that smooth surface morphology propagates upward toward the upper surface 106s resulting in the upper surface 106s being smooth as well. In at least some embodiments, support layer 108 provides a template for the growth of a crystalline structures within the material (e.g., Pt) of the bottom electrode 106 to establish a relatively smooth surface for bottom electrode 106, which, in turn, can provided for a relatively smooth interface 150 upon which to deposit a subsequent layer of material such as IMO 118 or CMO 120.

A relatively smooth interface, such as interface 150, promotes formation of uniform structures in subsequently deposited materials, such as IMO material 118. As the thickness of IMO material 118 becomes more uniform, a magnitude 190 of deviations in the Z direction decreases relative to a plane (e.g., parallel to an X-Y plane parallel to or in interface 150) passing through a surface of IMO material 118, at least in some cases. With reduced magnitudes in deviations ΔT of thickness 190 (e.g., reduced values of surface roughness), a current I passing through IMO material 118 per unit area (e.g., a current density 194) is more uniform over a surface of the IMO material 118. As shown, as the magnitudes in deviations 190 or the surface roughness is reduced for a surface of IMO material 118, the current I or current densities 194 through unit cross-sectional areas 192 become more uniform or substantially equivalent in magnitudes. In particular, a distribution of current I or current densities 194 uniformly through and across the surface of IMO material 118 promotes a reduction or elimination of instances that certain magnitudes of current occur at non-uniform thicknesses of IMO material 118 (e.g., large thickness deviations 190 leading to large ΔTs), thereby reducing or eliminating the degradation of the structure and/or functionality of IMO material 118 that otherwise might contribute to memory cell “wear-out.” Non-uniform thicknesses of IMO material 118, in some examples, can coincide with or be located at upper surface portions with surface roughness magnitudes that exceed, for example, the magnitudes of variation 190. In some instances, surface roughness magnitudes that exceed 1.5 Angstroms can relate to or produce non-uniform thicknesses of IMO material 118. Therefore, support layer 108 can delay or eliminate wear-out, thereby enhancing cycling endurance over a number data operations cycles such as program and erase cycles, for example, and, thus, the reliability of memory cell 101 and memory element 104.

In some embodiments, support layer 108 also can provide a growth template (e.g., via bottom electrode 106) for forming crystalline structures of CMO material 120 as depicted in memory element structure 110b, whereby the smooth upper surface 106s of bottom electrode 106 and/or crystalline structures of CMO material 120 are formed to provide a smooth or a substantially smooth upper surface 120s upon which IMO material 118 is subsequently deposited. As depicted by dashed line 111b, implementation of support layer 108 influences the structure and/or functionality of CMO material 120. Here, an uppermost layer of the previously deposited CMO layer(s) 120 includes the smooth upper surface 120s and the IMO 118 is deposited on the smooth upper surface 120s of the uppermost CMO layer. Therefore, memory element structure 110a depicts an example where the first layer of memory materials to be deposited on the bottom electrode 106 comprises the IMO 118 and memory element structure 110b depicts an example where the first layer of memory materials to be deposited on the bottom electrode 106 comprises the CMO 120. Memory element structure 110b is also operative to provide the current I or current densities 194 through unit cross-sectional areas 192 that become more uniform or substantially equivalent in magnitudes when the IMO 118 is deposited on smooth CMO surface 120s instead of a smooth bottom electrode surface 106s.

In some embodiments, support layer 108 is operative as a buffer layer to filter out structural imperfections that might propagate from an amorphous or polycrystalline structure upon which memory cell 101 is formed. For example, array line 124 may be formed on or in a material that is amorphous or polycrystalline. An example of such a material includes a dielectric layer of material, such as SiO₂ or SiNx. Support layer 108 can be formed to ensure smooth or a substantially smooth interface between IMO material 118 and bottom electrode 106 or CMO material 120 and bottom electrode 106 when memory cell 101 is formed over SiO₂ or SiNx, for example. In one example, a support layer 108 can be formed to include a planarized surface (e.g., via CMP processing) that provides for relatively smooth interface 150.

According to some embodiments, support layer 108 is configured to have an orientation that influences the grain orientation of the material of an electrode, such as bottom electrode 106. Electrodes 102 and 106 can be formed from an electrically conductive material, such as a metal or metal alloy (e.g., a noble metal or a combination of noble metals). In a specific example, electrodes 102 and 106 can be formed of platinum (Pt) and may be deposited to a thickness of, for example, about 1250 Angstroms or less. Therefore, support layer 108 can influence the orientation of crystal structures and grains of platinum of bottom electrode 106 such that the surfaces of the grains are aligned or oriented in a similar direction (e.g., the surfaces of the grains of platinum being in the 001 orientation and having a relatively low surface energy).

According to some embodiments, the support layer 108 can include one or more layers of a conductive metal oxide (CMO) including but not limited to PrCaMnOₓ (PCMO), other perovskite material-based CMOs, conductive binary oxides, and manganites, just to name a few. In some embodiments the support layer is made from a material that is not electrically conductive. In other embodiments the support layer is made from an electrically conductive material. Suitable materials for the support layer 108 are described below. In some cases, support layer 108 can include a conductive binary metal oxide. IMO material 118 can include a material to form a tunnel oxide-based structure or an electrolytic tunnel barrier. Suitable materials for the IMO 118 are described below. IMO material 118 can have a thickness of approximately 50 Angstroms or less. The thickness can be function of the application, the material selected, and voltage magnitudes chosen for data operations to memory cells (e.g., read voltages, write voltages, program and erase voltages) that facilitate tunneling. In some embodiments, IMO 118 can comprise multiple layers of IMO materials and those materials need not be the same. When multiple IMO layers are used, a combined thickness of all the IMO layers is approximately 50 Angstroms or less.

CMO material 120 can include a conductive metal oxide (CMO) or other perovskite material that typically exhibits memory characteristics. CMOs can be formed from a variety of perovskite materials and may include a mixed valence oxide having an amorphous structure, a substantially mixed crystalline structure, a polycrystalline structure, or some combination of those structures. Perovskite materials, such as CMO, may include two or more metals being selected from a group of transition metals, alkaline earth metals and rare earth metals. Suitable materials for the CMO material 120 are described below. The CMO 120 can comprise one or more layers of CMO material such as a bi-layer or tri-layer CMO structure. For example, the structure can include a CMO seed layer with a CMO active layer deposited on the CMO seed layer and a CMO cap layer deposited on the CMO active layer. In some embodiments the cap layer or the seed layer can be eliminated. The thicknesses of the multi-layer CMO structure can vary and in some embodiments, the cap and/or seed layers have thicknesses that are less than a thickness of the active CMO layer.

According to various embodiments, memory element 104 is a resistive memory element configured to maintain a resistive state representative of a data stored therein. The resistive state (i.e., the data) is retained in the absence of electrical power; therefore the memory element 104 stores non-volatile data. As used herein, the term “discrete memory element” can refer, at least in some examples, to a memory cell having a structure that includes no more than memory element 104, electrodes 102 and 106, and support layer 108. For example, a discrete memory element can be a gateless two-terminal device. Memory element 104 can as a discrete memory element constitute a memory cell, according to at least some embodiments. In some examples, a programmed state is a high resistance state (e.g., a logic “0”), and an erased state is a low resistance state (e.g., a logic “1”), thereby establishing a magnitude of an access current that is relatively lower for the programmed state and is relatively higher for the erased state. A range of resistive states can represent more than two memory states (i.e., multiple bits per memory cell can be stored as a multi-level cell). The memory element 104 can store data as a plurality of conductivity profiles that can be non-destructively determined (e.g., read) by applying a read voltage across first and second terminals (e.g., electrodes 106 and 102) of the memory element 104 and the plurality of conductivity profiles can be reversibly written by applying a write voltage across the first and second terminals. Unlike conventional non-volatile Flash memory, a write operation to the memory element(s) 104 does not require a prior erase or block erase operation. Moreover, a Flash File System (FFS) and/or Flash Operating System (Flash OS) are not required to manage data or for performing data operations to the memory element(s) 104.

Note that in combination with implementation of the support layer 108, other structures of memory cell 101 can include features that further facilitate formation of IMO material 118 having a uniform thickness (or a substantially uniform thickness). Some of these features relate to select processing techniques described below. According to alternate embodiments, other materials and layers can be disposed between those structures shown in FIG. 1. While the term “bottom electrode” can refer to a electrode that is formed closer to a substrate (not shown) than other electrodes, the description of structures and techniques relating to a bottom electrode can apply to a top electrode.

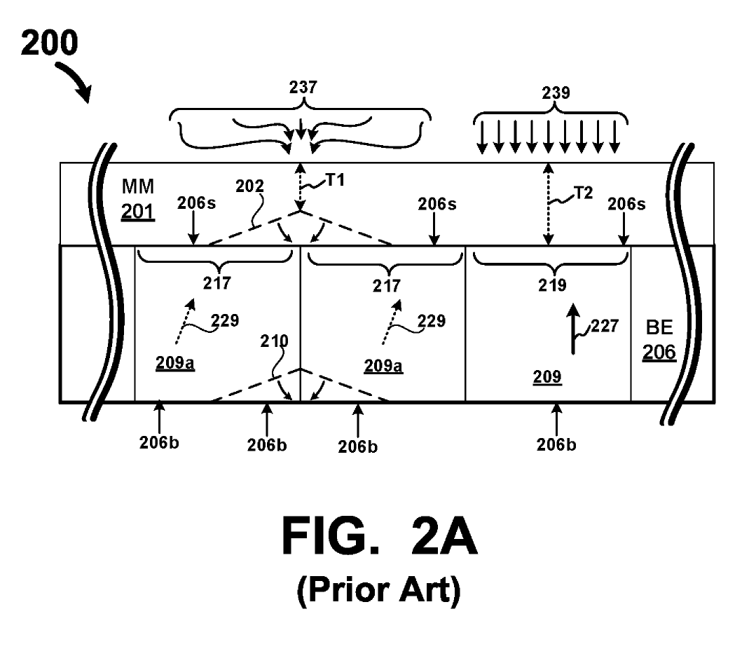

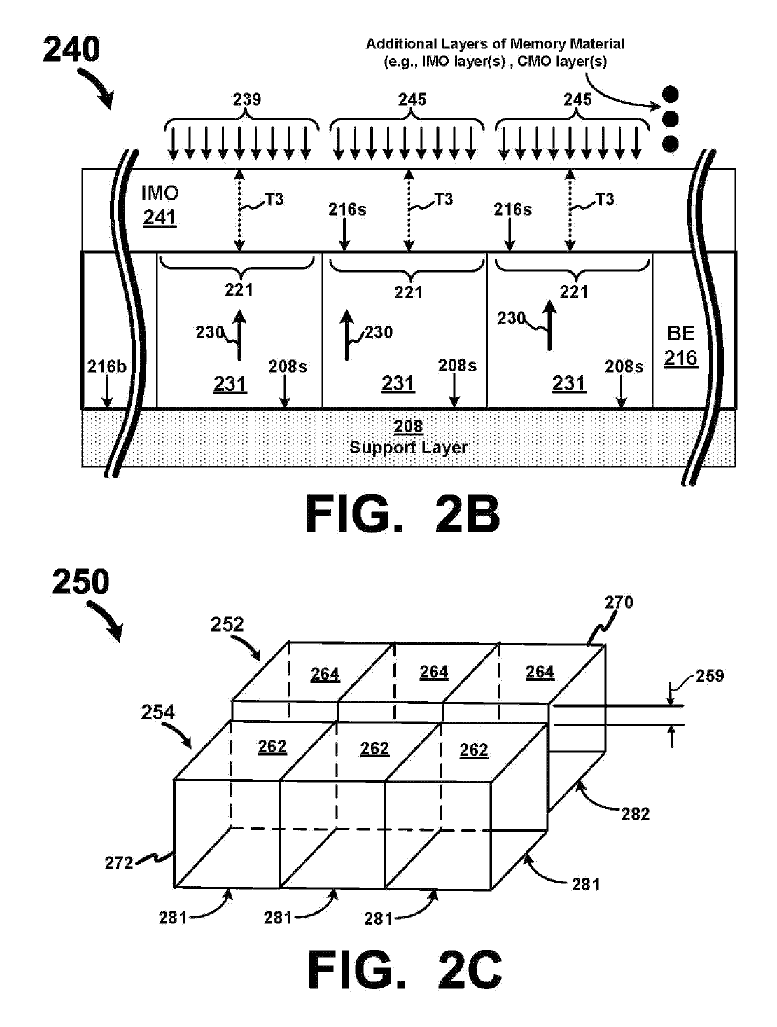

FIG. 2A depicts a portion of a conventional memory element structure 200 in which a bottom electrode (BE) 206 is not formed on top of a support layer. An upper surface 206s of the BE 206 includes some non-planar (i.e., non-smooth) regions having surface roughness 202. For purposes of illustration and explanation other regions are depicted that do not have surface roughness 202. The surface roughness 202 can be caused by surface roughness in a layer of material the BE 206 is deposited on such that a bottom surface 206b includes surface roughness 210 that is replicated (e.g., propagates into) in upper surface 206s causing the surface roughness 202. A layer of memory material (MM) 201 deposited on upper surface 206s of the BE 206 can have variations in thickness along the upper surface 206s such that portions of layer MM 201 that are above regions having surface roughness 202 have a thickness T1 and portions of layer MM 201 that are not above regions 202 have a thickness T2 that is greater than thickness T1 (i.e., T2>T1). As one example of how surface roughness can affect one or more layers of memory material, if layer 201 comprises an IMO layer, then a current flow 237 in regions proximate the thinner thickness T1 can be higher than a current flow 239 proximate the thicker thickness T2. If material 201 is an IMO material that is disposed over irregular portions 202, then the thickness T1 of material 201 at irregular portions 202 is generally less than the thickness T2 at portions of the relatively smooth upper surface 206s that are proximately above grains 209. The current 237 passing through a surface of IMO material 201 flows through at an increased amount per unit area (e.g., an increased current density) at portions of IMO material 201 having thickness T1. The non-uniform amount of current 237 increases structural stresses on IMO material 201 over multiple write and erase cycles and negatively impact cycling endurance.

Surface roughness can be caused by other factors such as a grain structure of BE 206. For example, grains 209a can include a grain orientation that is skewed in a non-preferred orientation denoted by dashed lines 229 and the skewed grain orientations 229 can contribute to surface roughness 202 on upper surface 206s. On the other hand, some other grains 209 of BE 206 have grain orientation 227 that is not skewed such that upper surface 206s does not exhibit the surface roughness 202 that exists in grains 209a. Accordingly, thickness T1 proximately above 217 grains 209a is less than the thickness T2 proximately above 219 grains 209. Even though some regions (e.g., above grains 209) do not have surface roughness 202, the layer 201 has variations in thickness that can negatively impact memory device performance and defeat consistent memory device characteristics (e.g., cycling endurance, tunneling current, etc.) among several memory devices, such as in a cross-point array. Further, inconsistent memory device characteristics that vary from die-to-die and/or wafer-to-wafer can result in low memory device yields. Ideally, it is desirable to eliminate or substantially reduce variations in thickness of thin-film layers of memory material, such as those caused by surface roughness.

Turning now to FIG. 2B, a portion of a memory element structure 240 includes an electrode structure formed in relation to a support layer, according to various embodiments. Structure 240 depicts a support layer 208 upon which a bottom electrode (BE) 216, is formed. Support layer 208 includes a substantially smooth upper surface 208s. An upper surface 216s of the BE 216 is also a smooth surface upon which to deposit IMO layer 241 having a substantially uniform thickness T3. The structure including IMO material 41 is disposed on or above bottom electrode 216. As shown, electrode 216 is formed to include metal crystalline structures or grains 231, such as grains of platinum (Pt). Support layer 208 can be configured to provide a template to establish grain orientations 230 for grains 231. In particular, support layer 208 establishes grain orientation 230 for grains 231 rather than the skewed grain orientation 229 of FIG. 2A that otherwise might occur. A current 245 passing through a surface of IMO material 241 flows through at a decreased amount per unit area (e.g., a decreased current density) at portions of IMO material 241 having thickness T3. The non-uniform amount of current 237 of FIG. 2A increases structural stresses on an IMO material over multiple write and erase cycles and can negatively impact cycling endurance. Here, regions 221 of BE 206 include the smooth upper surface 216s having minimal or low surface roughness that contribute to uniform thickness T3 of IMO 241 and uniform current flow 245 during data operations to the resulting memory element.

Thickness T3 corresponds to the thickness of IMO material 241 disposed over surface portions 221 of grains 230 having orientation 231. Surface portions 221 can be co-planar and share a common plane, thereby providing for a relatively smooth interface between BE 216 and IMO material 241. In some cases, surface portions 221 are at least in planes parallel to each other. Support layer 208 operates to provide grain orientations 231 rather than grain orientations 229 for grains 209a of FIG. 2A, thereby reducing or eliminating irregular portions 202 to establish surface portions 221. Thus, the amount of current 245 is distributed uniformly over the area of surface portions 221, to reduce or eliminate structural stresses on IMO material 241 over multiple data operations cycles (e.g., write cycles). Uniform current 245 illustrates equivalent amounts of current or current densities flowing through uniform thicknesses T3 of IMO material 241.

In some embodiments, support layer 208 provides for an RMS value of surface roughness less than or equal to about 12 Angstroms (e.g., for support layer 208, electrode 216, or IMO material 241). According to some embodiments, support layer 208 provides for an RMS value of surface roughness for IMO material 241 that is less than or equal to about 1.5 Angstroms. In some cases, the RMS value of surface roughness for IMO material 241 is less than or equal to about 6 Angstroms. As used herein, the term “smooth surface” can refer to any surface of a structure in a memory cell 101, such as a surface of an electrode, a layer of CMO, a layer of IMO, or a layer of another thin-film material used in the memory element 104 (e.g., glue layers, adhesion layers, diffusion barriers, etc.). For example, a smooth surface of a bottom electrode can have values of RMS surface roughness in range from about 6 Angstroms to about 12 Angstroms, or less. Examples of a smooth surface of an IMO material include RMS surface roughness values from about 0.5 Angstroms to about 1.5 Angstroms, or less. As used herein, the term “substantially smooth surface” can refer to an enlarged range of values of RMS surface roughness (e.g., any RMS surface value in a range that extends up to about 50 Angstroms). As used herein, the term “smooth interface” can refer to an interface between an electrode and an IMO material in which the RMS surface roughness of the electrode is from about 6 Angstroms to about 12 Angstroms, or less, and the RMS surface roughness of the IMO material is from about 0.5 Angstroms to about 1.5 Angstroms, or less. As used herein, the term “substantially smooth interface” can refer to an interface between an electrode and an IMO material in which either the RMS surface roughness of the electrode is within a range that includes from about 6 Angstroms to about 12 Angstroms (e.g., a range that extends up to about 50 Angstroms), or the RMS surface roughness of the IMO material is within a range that includes from about 0.5 Angstroms to about 1.5 Angstroms (e.g., a range that extends up to about 10 Angstroms). As used herein, the term “uniform thickness” can refer to a thickness of, for example, an IMO material at a surface having an RMS surface roughness value of from about 0.5 Angstroms to about 1.5 Angstroms, or less. As used herein, the term “substantially uniform thickness” can refer to a thickness of, for example, an IMO material at a surface having an RMS surface roughness value within a range that includes from about 0.5 Angstroms to about 1.5 Angstroms (e.g., a range that extends up to about 10 Angstroms). By reducing surface roughness of the surfaces of electrode 216 and/or IMO material 241, the total is through the IMO material can be less than otherwise might be the case. Note that while the smoothness of an interface or surface and the thickness of IMO material can be expressed in values of RMS surface roughness, other representations of surface roughness (e.g., arithmetic average surface roughness) or other metrics can be used to describe the smoothness of an interface or surface and the thickness of IMO material and the present application is not limited to surface roughness measured using RMS metrics.

Moving on to FIG. 2C, a diagram 250 depicts grains of a crystalline material disposed over a support layer, according to some embodiments. As shown, a row 254 of grains includes a number of grains 272, and a row 252 of grains includes a number of grains 270 disposed adjacent to neighboring row 254. A support layer (not shown) positioned below and in contact with bottom surfaces 281 and 282 provides for grain orientations and structures for the crystalline material such that variations in surface portions between neighboring grains is between about 5 Angstroms to about 10 Angstroms, or less. Therefore, an IMO material disposed over the crystalline material can have a thickness that varies less than from about 5 Angstroms to about 10 Angstroms, or less, over an area (e.g., an area larger than the sampling length for determining an RMS surface roughness value) that includes surface portions 262 and 264 of multiple rows of grains 270 and 272. In some embodiments, grains 270 and 272 are composed of metallic material, such as platinum. In some embodiments, grains 270 and 272 can be composed of a CMO material, such as a manganite, a perovskite, or a conductive binary metal oxide, just to name a few.

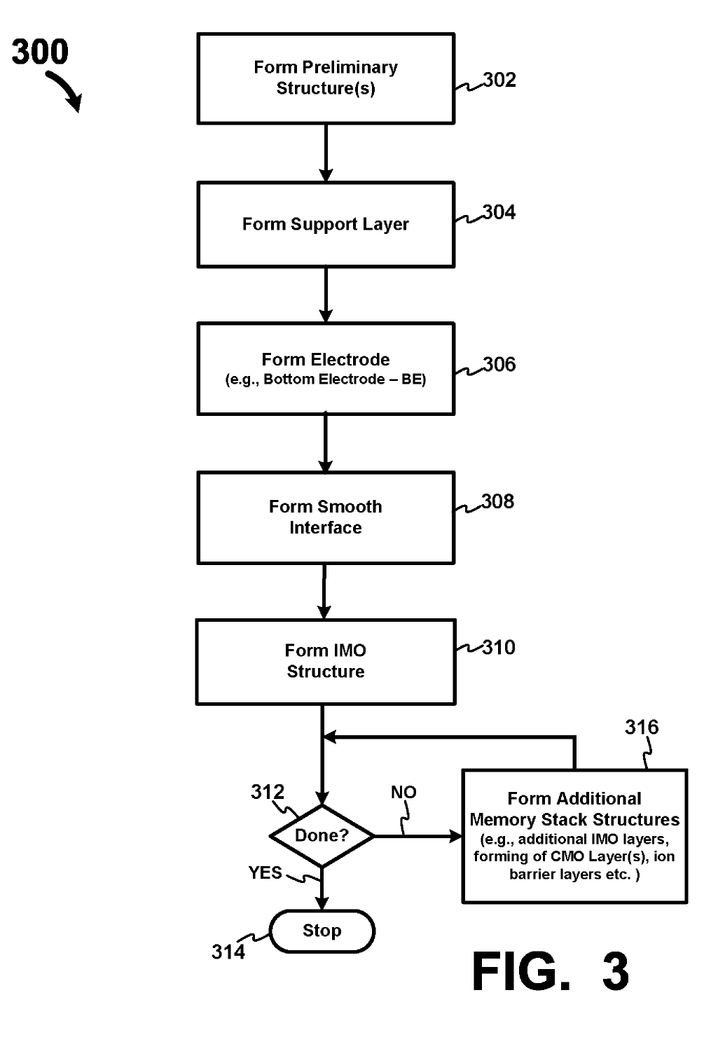

FIG. 3 depicts an example of a flow 300 for forming a support layer, according to various embodiments. At stage 302 of flow 300, a preliminary structure or structures are formed. For example, a dielectric layer is formed optionally upon which a memory cell or memory element is fabricated. The dielectric layer serves as a support for an array line and/or as an insulator between adjacent memory cells/elements. At stage 304, a support layer (e.g., layer 108 or 208) can be formed using a variety of thin-film layer deposition techniques, examples of which include, but are not limited to, physical vapor deposition (PVD), sputtering, reactive sputtering, co-sputtering, chemical vapor deposition (CVD), atomic layer deposition (ALD), and the like. At stage 306, an electrode is formed as (e.g., 106 or 216), for example, a noble metallic structure by, for example, using epitaxial deposition processes or a plating process. At stage 308, a smooth interface is formed (e.g., using CMP). In some examples, a support layer provides for the smooth interface. In other examples, additional processing can be applied to one or more surfaces in combination with the processes used on the support layer. For instance, additional processing can include performing a smoothening operation (e.g., CMP) on a surface of an electrode. To illustrate, the surface of the electrode can be exposed to chemical-mechanical planarization (CMP) processes to yield a planarized electrode having a smooth and planer upper surface (e.g., surface 106s or 216s). CMP or other like processes can yield an atomically smooth and relatively clean surface (e.g., with no or reduced amounts of impurities) for the electrode to promote nucleation growth of IMO material or any other material, including CMO material. At stage 310, one or more layers of an IMO material are disposed over the surface of an electrode or other crystalline material. In some examples, IMO material can be formed by using CMO material deposition techniques with subsequent ion implementation to form the IMO material. At stage 312 if all processing is done, then flow 300 proceeds to YES branch and terminates at stage 314. If additional processing steps are required, then flow 300 proceeds to NO branch and additional processing continues at stage 316 where additional memory stack structures are formed. At stage 316, additional layers of thin-film materials can be formed (e.g., deposited, etched, etc.) such as additional IMO layers, one or more layers of CMO material, electrode layers, ion barriers (e.g., oxygen or metal ion barriers), glue layers, adhesion layers, barrier layers, anti-reflection layers, layers for optional NOD or selection devices, just to name a few. Upon completion of the additional processing at stage 316, the flow 300 can terminate at stage 314.

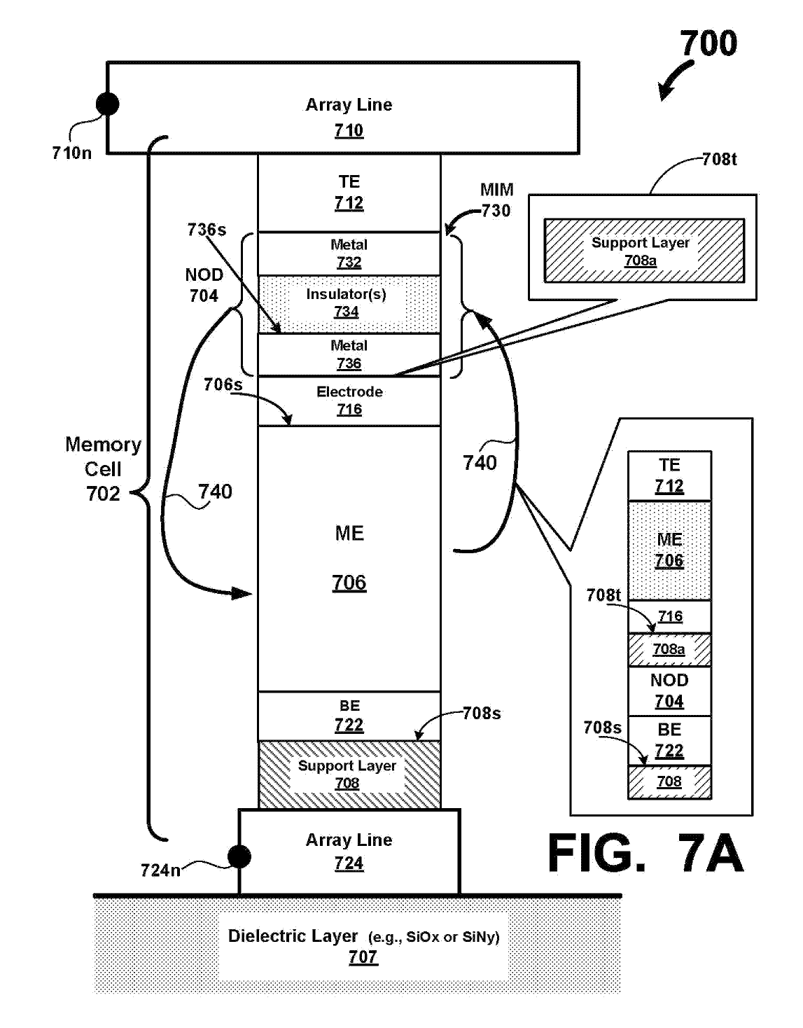

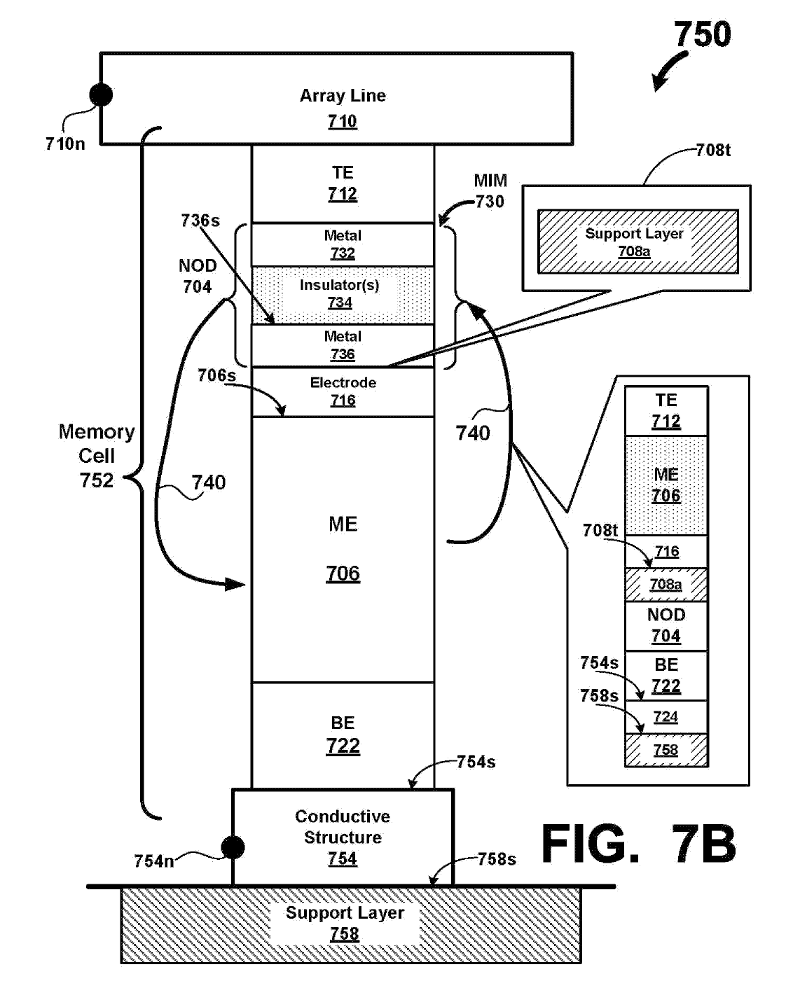

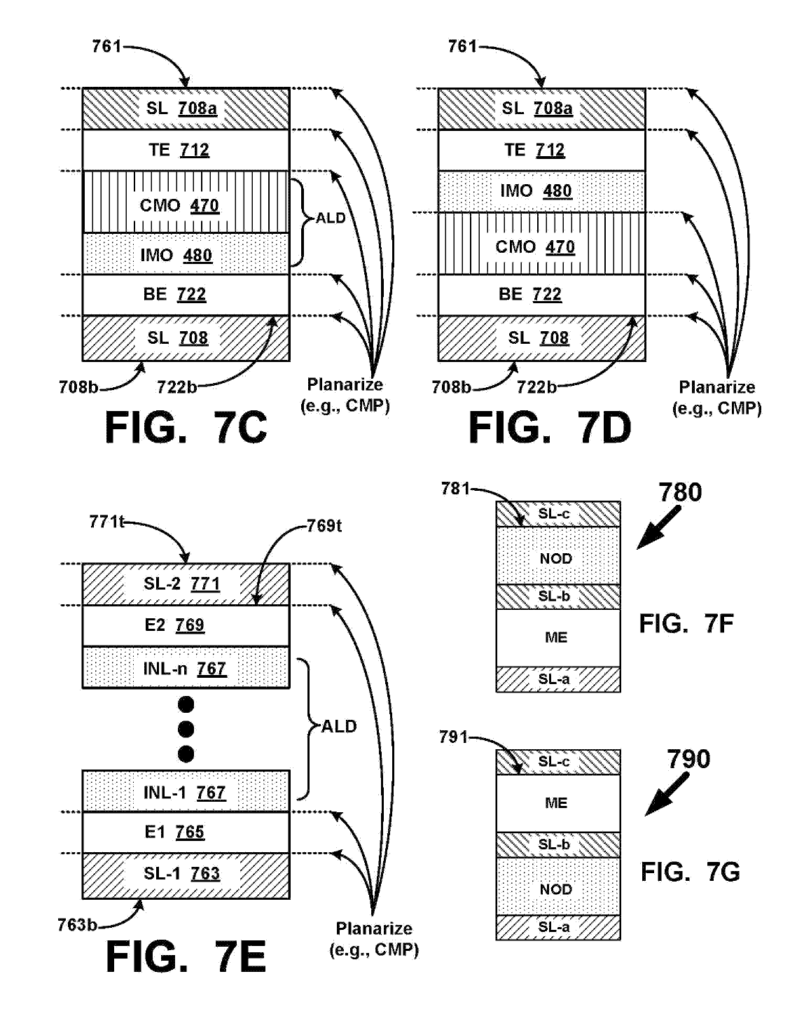

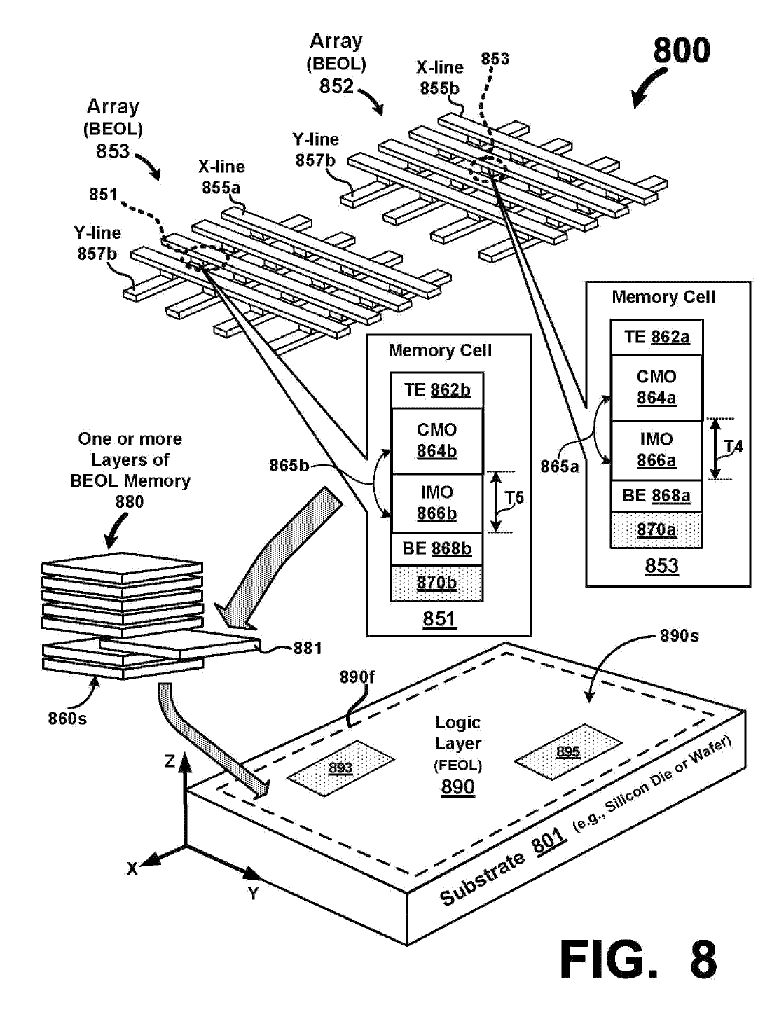

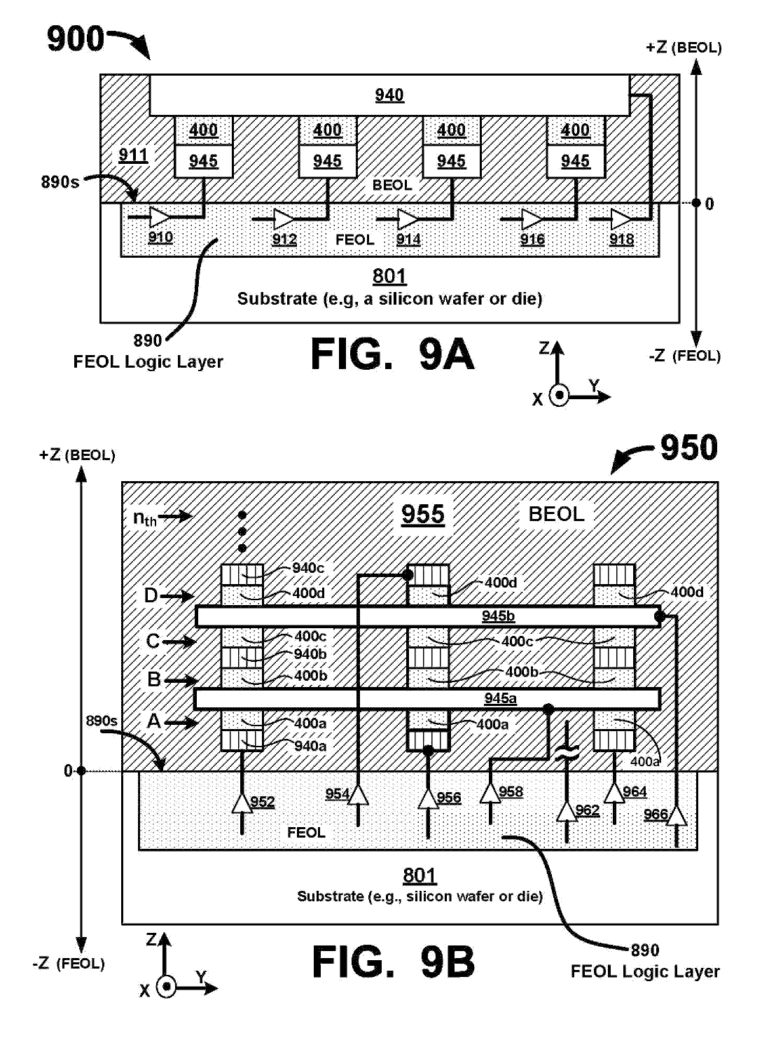

FIG. 4 depicts an example of a memory cell and arrayed memory cells according to various embodiments. In this example, a memory cell 400 includes a memory element 402, which, in turn, includes CMO material 470 and IMO material 480. Memory element 402 further includes two terminals 454 and 456 that can be the above mentioned electrodes. Terminals 454 and 456 can be electrically coupled with or can be formed as electrodes 412 and 416. The electrodes (412, 416) can be made from an electrically conductive material including but not limited to, a metal, a metal alloy, platinum (Pt), gold (Au), silver (Ag), iridium (Ir), iridium oxide (IrOₓ), ruthenium (Ru), palladium (Pd), aluminum (Al), a conductive metal oxide (CMO), and the like. Further, memory element 402 can include an electrically conductive support layer (“Support”) 418, upon which electrode 416 (e.g., bottom electrode—BE) is formed. Other electrically conductive support layers having a function similar or identical to support layer 418 (see support layer 708a in FIG. 7) can be disposed in memory element 402, such as between CMO material 470 and an optional NOD 414 (e.g., a MIM). Here memory element 402 can be oriented such that the BE 416 is connected with the IMO 480 as described above and depicted by arrow 461, or the BE 416 is connected with the CMO 470 as depicted by arrow 463. In some implementations, such as in multi-layer vertically stacked memory arrays (see FIG. 9B), memory elements 402 in one memory layer can be oriented with their respective IMO 480 in contact with the BE 416 (arrow 461) and memory elements 402 in an adjacent memory layer can be oriented with their respective CMO 470 in contact with the BE 416 (arrow 463). Therefore, memory elements 402 in adjacent memory layers have inverted orientations as described in pending U.S. patent application Ser. No. 13/171,350, filed Jun. 28, 2011, and titled “Multilayer Cross-Point Memory Array Having Reduced Disturb Susceptibility”, already incorporated by reference herein.

In at least some embodiments, memory cell 400 can optionally include a non-ohmic device (NOD) 414 or other type of selection device such as a diode (e.g., 1D-1R or 2D-1R) or a transistor (e.g., 1T-1R or 2T-1R), which, in turn, can be formed on the memory element 402 (e.g., either above or below memory element 402). NOD 414 can be a “metal-insulator-metal” (MIM) structure that includes one or more layers of electronically insulating material that are in contact with one another and sandwiched between metal layers (e.g., electrodes), or NOD 414 can be a non-linear device. Non-limiting examples of NODs and selection devices include but are not limited to those described in U.S. Pat. No. 7,995,371, issued on Aug. 9, 2011, and titled “Threshold Device For A Memory Array” and in U.S. Pat. No. 7,884,349, issued on Feb. 8, 2011, and titled “Selection Device for Re-Writable Memory” which are already incorporated herein by reference in their entirety. NOD 414 can be positioned above the memory element 402 as depicted in FIG. 4 or the NOD 414 can be positioned below the memory element 402 (not shown). In some embodiments an intermediate electrode 415 may be positioned between the NOD 414 and the memory element 402. Memory cell 400 can be formed between conductive array lines, such as array lines 492 and 494. Thus, memory cell 400 can be formed in an array with other memory cells, and the array can be a cross-point array 499 with groups of conductive array lines 492 and 494. For example, array line 492a can be electrically coupled with the electrode 412 of the memory cells 400 and/or may be in contact with a surface of the electrode 412. Array line 494a can be electrically coupled via support layer 418 with the electrode 416 of the memory cells 400 and/or may be in contact via support layer 418 with a surface of electrode 416.

Further to FIG. 4, two other memory cells are shown disposed in array 499. A first memory cell is disposed between array line 492b and array line 494b, whereas a second memory cell is disposed between array line 492c and array line 494b. In accordance to various embodiments, support layers 418 formed in each of the two memory cells provides for magnitudes of current flow through each of the memory cells (I1 and I2) that varies, for example, less than about 50% from each other (i.e., ΔI≦50%). More preferably, magnitudes of current flow through each of the memory cells (I1 and I2) varies, for example, less than about 20% from each other (i.e., ΔI≦20%). As another example, current flow through each of the memory cells (I1 and I2) varies less than about 10% from each other (i.e., ΔI≦10%). Therefore, the reliability in the operation of memory cells 400 in array 499 is enhanced.

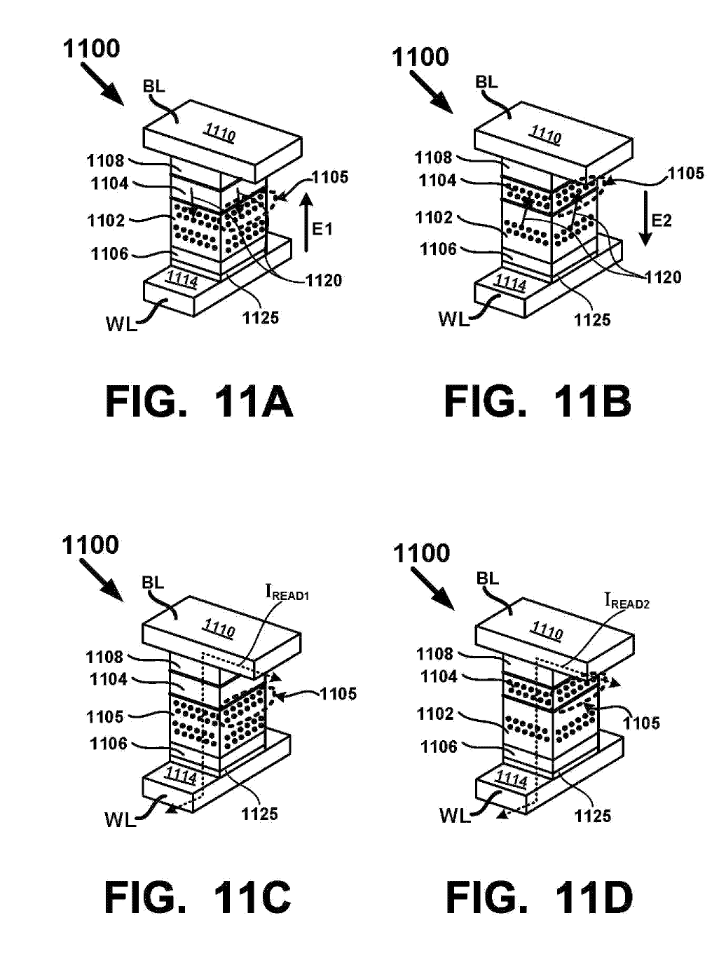

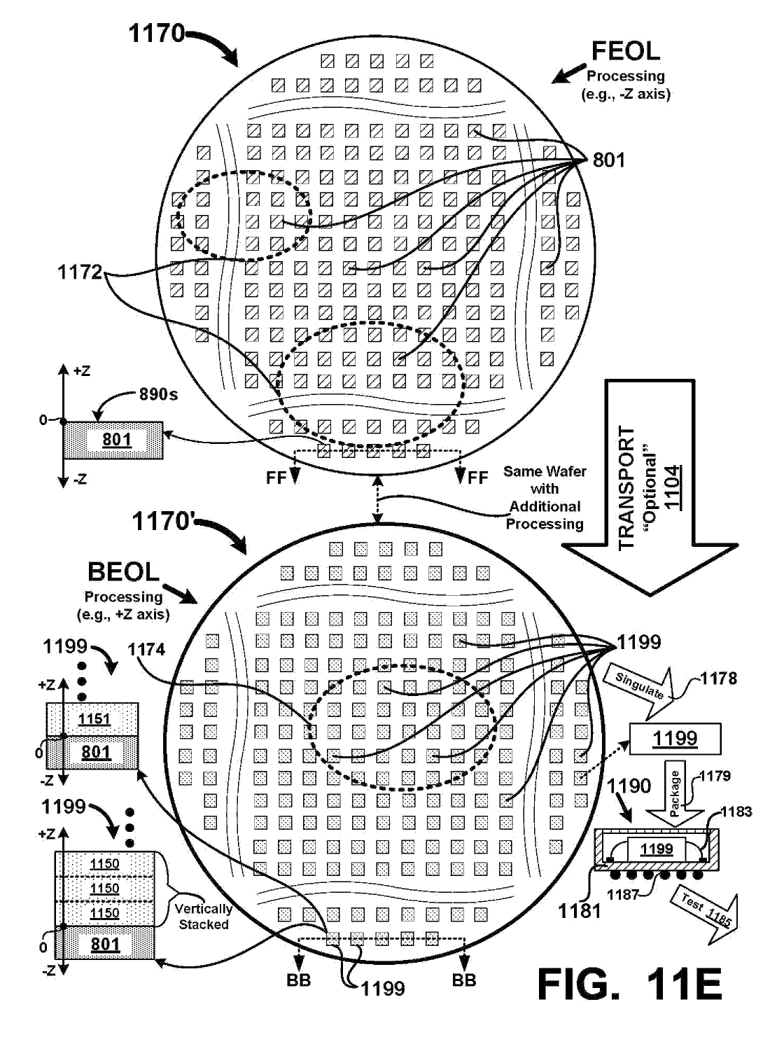

Although only one cross-point array 499 is depicted, each layer of memory can include at least one of the cross-point arrays 499 and those arrays need not be the same size. Furthermore, although only one layer of memory is depicted, additional layers of back-end-of-the-line (BEOL) memory can be fabricated above the depicted layer along the +Z axis (see FIG. 9B and FIG. 11E). Active circuitry fabricated front-end-of-the-line (FEOL) on a substrate, such as semiconductor substrate (e.g., a Silicon—Si wafer or die) are not depicted in FIG. 4 but will be described in greater detail below with regard to FIGS. 8, 9A, 9B, and 11E. At least a portion of the active circuitry (e.g., CMOS circuitry) is electrically coupled with the array lines of array 499 and operative to perform data operations on one or more memory elements 402 in array 499.

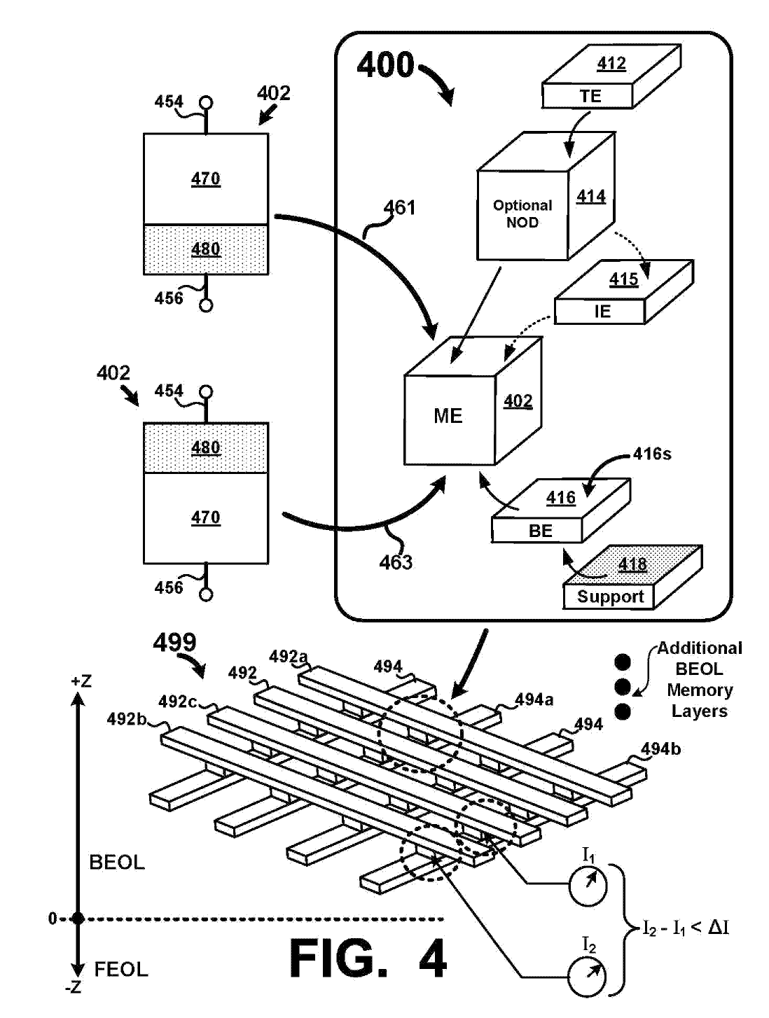

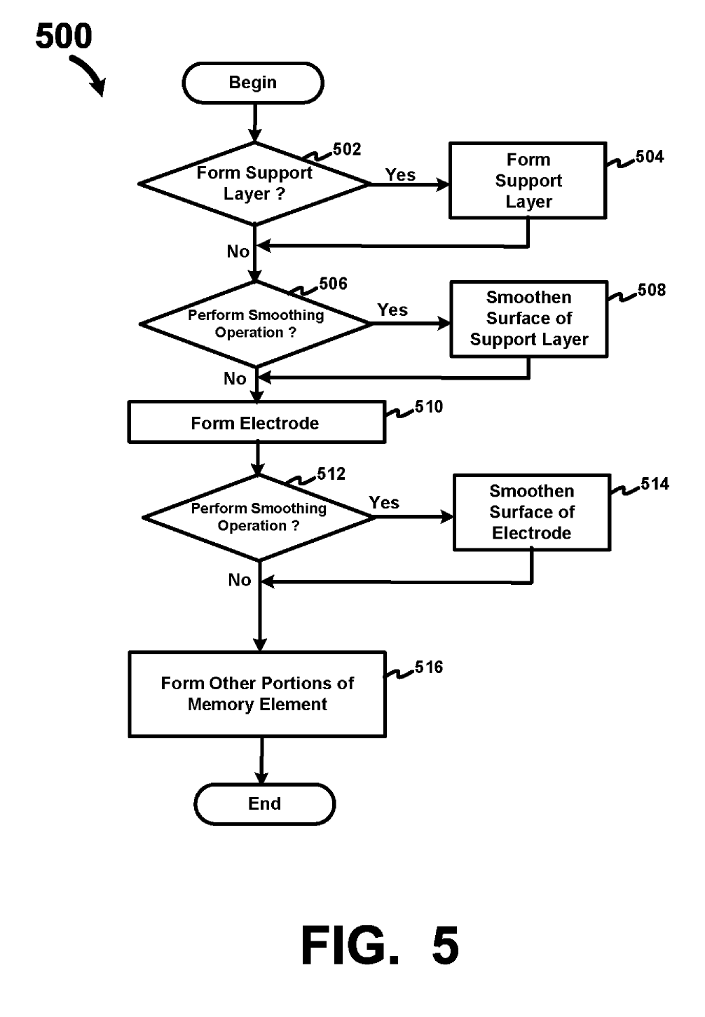

FIG. 5 depicts an example of a flow 500 to smoothen surfaces of structures (e.g., support layers, electrodes, etc.) in a memory element, according to various embodiments. At stage 502 of flow 500, a determination is made whether to form a support layer. If so, the YES branch is taken and a support layer (e.g., 108, 208, 418) is formed at stage 504. At stage 506, a determination is made whether to perform a smoothening operation, such as CMP, on the support layer. If so, the YES branch is taken and a smoothening operation is performed at stage 508 to yield a planarized upper surface of the support layer. If no support layer is to be formed then the NO branches at stages 502 and 506 can be taken. At stage 510, an electrode (e.g., 106, 216, 416) is formed. The electrode may be formed as an epitaxial layer including, for example, a noble metal. In some embodiments, the conditions of epitaxial deposition under which the electrode is formed are sufficient to form a relatively smooth surface. For example, the formation of a platinum electrode can be under temperatures that are sufficiently high enough to promote the growth grain surfaces in the platinum that are oriented in a preferred direction, such as in a 001 orientation or other orientation. At stage 512, a determination is made whether to perform a smoothening operation, such as CMP, on the electrode. If so, the YES branch is taken and a smoothening operation is performed at stage 514 to yield a planarized upper surface for the electrode. At stage 516, other structures of a memory element are formed even if the NO branch from stage 512 is taken.

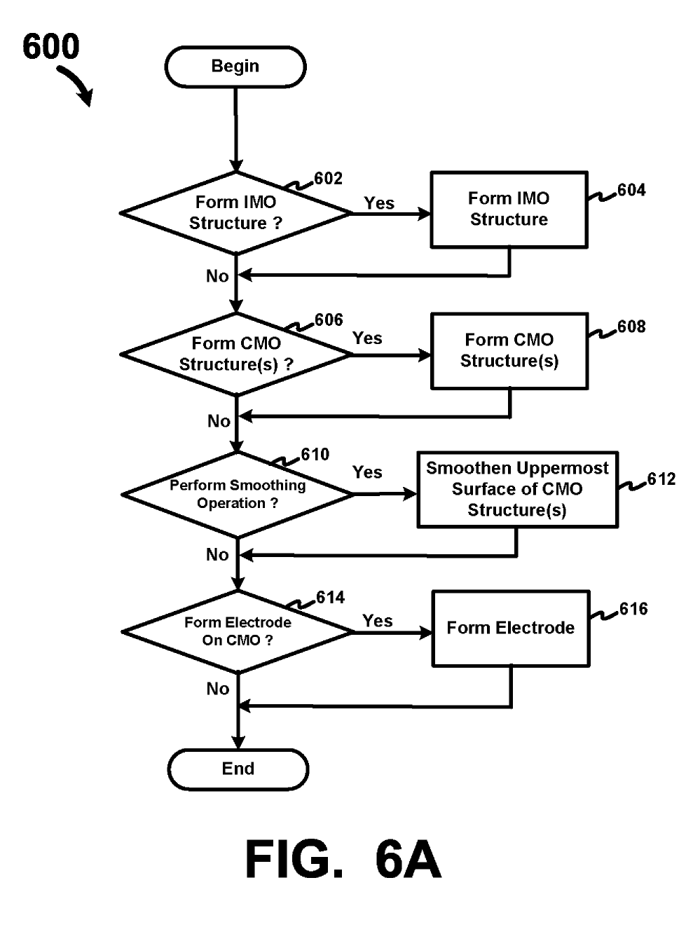

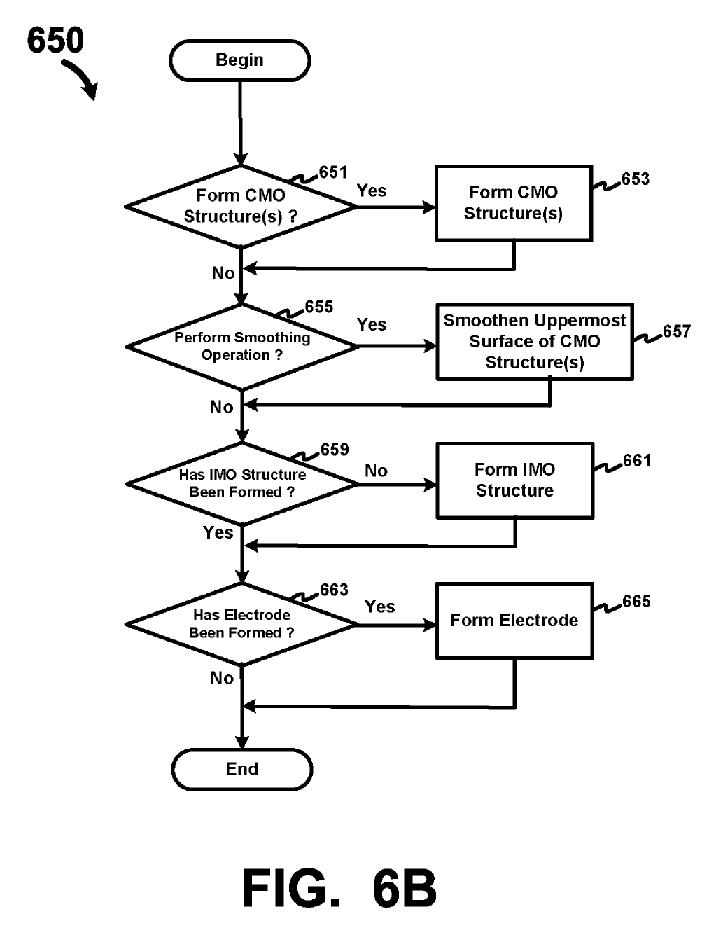

FIG. 6A depicts an example of a flow 600 to form a memory element, according to various embodiments. At stage 602 of flow 600, a determination is made whether to form one or more layers of an IMO material. If so, YES branch is taken and one or more layers of IMO material are deposited, for example, over an electrode at stage 604. Here, the electrode upon which the IMO layer(s) are formed may be an electrode that was previously deposited on the aforementioned support layer (e.g., 108, 208, 418, 708, 708a, 870a, 870b). In some embodiments, atomic layer deposition (ALD) is used to promote uniformity of the thickness of the layer(s) of IMO material. Other deposition techniques can also be used in place of, in combination with, and in addition to ALD, such as physical vapor deposition (PVD), sputtering, reactive sputtering, co-sputtering, chemical vapor deposition (CVD), and the like. In various embodiments, the IMO material can be formed as a tunnel oxide or an electrolytic tunnel barrier layer. At stage 606 of flow 600, a determination is made whether to form one or more layers of CMO material on top of the previously deposited layer(s) of IMO. If so, at a stage 608 one or more layers of CMO material are deposited, for example, over an uppermost layer of a previously deposited layer(s) of IMO material. A process such as ALD can be used to deposit the CMO material. Here, if the IMO layer(s) were formed at the stage 604, the structure of the memory element after stage 608 is BE/IMO/CMO. In some applications, the one or more layers of CMO material can be formed (e.g., deposited) in whole or in part using ALD. For example, a high impact deposition process (e.g., PVD or sputtering) may cause damage to the IMO material the CMO will be deposited on. Accordingly, the forming of the CMO material over the IMO material can include beginning the deposition process using a soft deposition process such as ALD to form at least a portion of the CMO. Subsequently, after the IMO material is covered by a sufficiently thick layer of the CMO material, the deposition process can be switched to a non-ALD process or hard deposition process. If multiple layers of CMO material are to be deposited, then at least the first layer of CMO to be deposited on the IMO material can be deposited using ALD (e.g., a soft process) and subsequent layers may optionally be deposited using another deposition process such as PVD (e.g., a hard process) or the like. At stage 610, a determination is made whether to perform a smoothening operation, such as CMP, upon an uppermost surface of the CMO material. If so, a smoothening operation is performed at stage 612 to yield a planarized surface of CMO material. At a stage 614 a determination is made whether to form an electrode (e.g., TE 102, 412, 712) on an uppermost layer of the CMO (e.g., on the planarized surface of the CMO material). If so, at a stage 616 an electrode is formed on the CMO material.

Alternatively, it may be desirable to form the CMO layer(s) first and then form the IMO layer(s) second. Accordingly, FIG. 6B depicts an alternative example of a flow 650 for forming a memory element. At a stage 651 a determination is made whether to form one or more layers of CMO material. If so, at a stage 653 one or more layers of CMO are formed, using a process such as ALD, for example. Here, the CMO layer(s) that are formed may be formed on an upper planar surface of an electrode that was previously deposited on the aforementioned support layer (e.g., 108, 208, 418, 708, 708a, 870a, 870b). In some embodiments, atomic layer deposition (ALD) is used to promote uniformity of the thickness of some or all of the layer(s) of CMO material. That is, different deposition processes can be used for two or more layers of CMO material formed upon each other. Other deposition techniques also can be used, such as physical vapor deposition (PVD), sputtering, reactive sputtering, co-sputtering, chemical vapor deposition (CVD), and the like. At a stage 665, a determination is made whether to perform a smoothening operation, such as CMP, upon an uppermost surface of the CMO material. If so, a smoothening operation is performed at stage 657 to yield a planarized surface of CMO material. At stage 659 of flow 650, a determination is made whether to form one or more layers of an IMO material on top of the previously deposited layer(s) of CMO material (e.g., on the planarized uppermost surface of the CMO material). If so, one or more layers of IMO material are formed at stage 661, for example, over the previously deposited layer(s) of CMO material formed at stage 653. ALD can be used to form the one or more layers of IMO material. At a stage 663 a determination is made whether to form an electrode (e.g., TE 102, 412, 712) on an uppermost layer of the IMO. If so, at a stage 665 an electrode is formed on the IMO material.

The flows 600 and 650 can both be used for form memory elements in the same memory device, such as in the case where memory elements in adjacent memory layers of a multi-layer BEOL memory device are inverted relative to one another as described in pending U.S. patent application Ser. No. 13/171,350, filed Jun. 28, 2011, and titled “Multilayer Cross-Point Memory Array Having Reduced Disturb Susceptibility”, already incorporated by reference herein.

FIG. 7A depicts a cross-sectional view depicting an exemplary memory cell formed between conductive array lines (e.g., in a cross-point array) in accordance with techniques described herein, according to one or more embodiments. As shown in diagram 700, memory cell 702 can include a non-ohmic device (“NOD”) 704, which is optional, and memory element 706 formed between array lines 710 and 724. Memory cell 702 includes a support layer 708, a bottom electrode 722, a memory element (ME) 706 including a structure formed with one or more layers of a CMO material (not shown) operative as a resistive structure of ME 706, and a structure formed with one or more layers of an IMO material (not shown). In turn, an electrode 716 is formed upon ME 706. For example, electrode 716 can be formed on an upper surface 706s of the ME 706 and that upper surface 706s can be the uppermost surface of the one or more IMO layers or of the one or more CMO layers, depending on how those layers are configured in the ME 706. Next, an optional metal-insulator-metal (MIM) structure 730 for NOD 704 that includes at least one insulator layer 734 formed between metal structures 732 and 736, with MIM structure 730 being formed upon electrode 716. A top electrode 712 can be optionally formed thereupon. In some embodiments, either array line 724 or support layer 708, or both, can be formed on a dielectric layer 707. Examples of a dielectric layer 707 include but are not limited to SiO₂ or SiNₓ. In some embodiments, the positions of memory element 706 and NOD 704 can be interchanged as depicted by arrows 740 such that the NOD 704 is positioned at the bottom of memory cell 702 and the ME 706 is positioned above the NOD 704. Therefore, another support layer 708a can be formed in addition to, or instead of, support layer 708. Thus, support layer 708a provides for a growth template for a layer of material to be deposited above the support layer 708a, such as metal layer 736 for NOD 704 or an electrode layer if an IMO layer or CMO layer is subsequently formed above support layer 708a. Other support layers (not shown) can be implemented in memory cell 702. Furthermore, when the NOD 704 is included in the memory cell 702, a support layer (e.g., 708) positioned under an electrode (e.g., 736) for the NOD 704 can serve a similar purpose for the one or more layers of insulator 734 in the MIM structure 730 so that the insulator(s) 734 are formed upon an electrode having a substantially planar and smooth upper surface with a surface roughness that does not result in the thickness variations described above in FIG. 2A and/or to provide an appropriate growth template for the material of the electrode 736. In FIG. 7A, the support layer(s) (e.g., 708 and 708a) are made from electrically conductive materials so that data operation voltage potentials applied to nodes 710n and 724n of conductive array lines 710 and 724 allow current to flow through the memory element 706 and the NOD 704 (if present) and for a read or write voltage to be applied across the memory element 706 during data operations. In some embodiments, the support layer need not be made from an electrically conductive material as will be described below in reference to FIG. 7B. However, if the one or more support layers are positioned electrically in series with the conductive array lines 710 and 724, then those support layers should be made from electrically conductive materials.

Sans the NOD 704, the ME 706 is a discrete two-terminal memory element having first and second terminals (e.g., BE 722 and TE 712) that are directly electrically coupled with the conductive array lines 710 and 724 and directly electrically in series with the conductive array lines 710 and 724. Therefore, the memory cell 702 absent the NOD 704 comprises only the ME 704 directly electrically in series with conductive array lines 710 and 724.

Turning now to FIG. 7B, an alternative exemplary memory cell 752 includes an electrically conductive structure 754 (e.g., a conductive array line) formed above a substantially planar and smooth upper surface 758s of a support layer 758 that is made from a material that is not electrically conductive, such as a dielectric material, for example. Here, the BE 722 is formed on top of an upper planar surface 754s of the conductive structure 754 such that subsequently deposited thin-film layers for the ME 706 are formed on a smooth and planar surface (e.g., the IMO layer(s) or CMO layer(s)). As described above, nodes 710n and 754n allow voltages for data operations to be applied to the memory cell 752. In some implementations, the conductive structure 754 can be eliminated and the BE 722 can be formed directly above the support layer 758 and node 754n can be electrically coupled with BE 722 instead of conductive structure 754. In some applications, the memory cell 752 can include the optional NOD 704. Furthermore, memory cell 702 can include more than one support layer, such as support layer 708a as described above. If positioned electrically in series between the array lines 710 and 754, then the additional support layer 708a should be made from an electrically conductive material.

In FIGS. 7C and 7D, cross-sectional views depict examples of two different configurations for a memory element formed on a support layer. Dashed lines represent portions of thin-film layers whose uppermost surfaces can optionally be planarized (e.g., using CMP) to form smooth and planar upper surfaces for the deposition of subsequent layers of thin-film materials. The position of the IMO layer(s) and CMO layer(s) in FIGS. 7C and 7D are reversed such that in FIG. 7C one or more layers of IMO 480 are formed on BE 722 followed by formation of one or more layers of CMO 470 on IMO 480. In contrast, in FIG. 7D one or more layers of CMO 470 are formed on BE 722 followed by formation of one or more layers of IMO 480 on CMO 470. Here, the one or more layers of IMO 480 and/or CMO 470 can be deposited using ALD. In some applications were multiple layers of IMO 480 and/or CMO 470 are implemented, some of the layers can be formed using ALD and other layers can be formed using other types of deposition processes such as PVD, for example. Support layers 708a can be used as a smooth and planar surface upon which to form additional thin-film layers for the memory element and/or memory cell, such as a NOD (e.g., a MIM device) on upper surface 761. As described above, application specific requirements will determine whether or not support layers 708 and 708a are made from electrically conductive materials. The configurations depicted in FIGS. 7C and 7D can be implemented in the same memory device, such as the case where inverted (e.g., in FIG. 7C) and non-inverted (e.g., in FIG. 7D) memory elements are used in multi-layer cross-point memory arrays, for example.

Referring now to FIG. 7E, a cross-sectional view depicts an example of a NOD formed using a support layer SL-1 763 upon which a first electrode E1 765 is formed followed by one or more insulating tunnel barrier layers INL-1 through INL-n. A second electrode E1 769 is formed on the uppermost insulating tunnel barrier layer. Depending on the application, a second support layer SL-2 771 can be formed on the second electrode E1 769. Here, some or all of the insulating tunnel barrier layers INL-1 through INL-n can be formed using ALD or other types of deposition processes such as PVD, for example. Dashed lines represent portions of thin-film layers whose uppermost surfaces can optionally be planarized (e.g., using CMP) to form smooth and planar upper surfaces for the deposition of subsequent layers of thin-film materials.

FIGS. 7F and 7G depict cross-sectional views of two configurations 780 and 790 for a memory element (ME) and a non-ohmic device (NOD) where in configuration 780 the NOD is formed above the ME and at least two support layers SL-a and SL-b are implemented. Optionally, a third support layer SL-c can be implemented on surface 781 and additional thin-film layers formed above the third support layer SL-c. On the other hand, in configuration 790 the ME is formed above the NOD and a third support layer SL-c can optionally be implemented on surface 791 and additional thin-film layers formed above the third support layer SL-c. The configurations depicted in FIGS. 7F and 7G and variations of those configurations can be implemented in the same memory device, such as the case where inverted (e.g., in FIG. 7C) and non-inverted (e.g., in FIG. 7D) memory elements are used in multi-layer cross-point memory arrays, for example.

In the configurations depicted in FIGS. 7C-7G, there can be variations of the structures depicted and the present invention is not limited to the examples shown. As one example, some of the support layers depicted need not be implemented in some applications, as in the case where the support layer is redundant or when an upper surface of at thin-film layer already has a surface morphology that does not require the benefits of a support layer. For example, support layer SL-1 763 can be eliminated if the electrode E1 765 of the NOD is formed on support layer SL 708a such that the configuration of FIG. 7F is implemented with the NOD on top of the ME. As another example, support layer SL 708 can be eliminated when the ME is formed on top of the NOD as depicted in FIG. 7G. Here, support layer SL-2 771 or SL-b can be used as the support layer upon which to form electrode BE 722.

FIG. 8 is a diagram depicting a perspective view on a portion of an integrated circuit (IC) in accordance with various embodiments. IC 800 includes cross-point memory arrays 852 and 853. Array 852 includes a memory cell 853 formed between X-line 855b and Y-line 857b, whereas array 853 includes a memory cell 851 formed between X-line 855a and Y-line 857a. In some cases, arrays 852 and 853 can be formed in a single BEOL memory layer 881 in one or more BEOL vertically-stacked layers of memory 880. In turn, one or more memory layers 880 are formed directly above substrate 801 (e.g., in direct contact with and above and upper surface 890s) and positioned over a logic layer 890 formed FEOL on a substrate 801 (e.g., a silicon die or wafer). Logic layer 890 includes periphery circuitry 893 and 895 formed using a semiconductor process technology such as complementary metal-oxide-semiconductor (“CMOS”) fabrication processes, for example, including relatively low voltage CMOS fabrications processes (e.g., to fabricate low voltage CMOS fabrication devices operable with gate voltages of 1.2 volts or less). One example of a suitable CMOS fabrication technology is sub-nanometer technology (e.g., 90 nm features sizes or less). In some embodiments, memory cell 851 can include a support layer (“support”) 870b, upon which an electrode 868b is formed. IMO layers(s) 866b are formed on electrode 868b, with CMO layer(s) 864b being formed over the IMO layer(s) 866b. An electrode 862b is formed over CMO layers(s) 864b. Memory cell 853 can include an electrically conductive support layer (“support”) 870a, upon which an electrode 868a is formed. IMO layers(s) 866a are formed on electrode 868a, with CMO layers(s) 864a being formed over IMO layers(s) 866a. An electrode 862a is formed over CMO layers(s) 864a. The thickness, T4, of IMO layers(s) 866b and the thickness, T5, of IMO layers(s) 866a, while uniform in thickness, can have different thicknesses that may yield different magnitudes of current through memory cells 851 and 853. For example, the magnitudes of current that flow through memory cells 851 and 853 can vary, for example, more than about 20% from each other, as logic layer 890 can include circuitry (not shown) to trim or to normalize the magnitudes of current that flow through memory cells of each individual array, such as arrays 852 and 853. As another example, the magnitudes of current that flow through memory cells 851 and 853 can vary, for example, more than about 10% from each other, as logic layer 890 can include circuitry (not shown) to trim or to normalize the magnitudes of current that flow through memory cells of each individual array, such as arrays 852 and 853.

In FIG. 9A, a die 900 for an integrated circuit (IC) or an application specific integrated circuit (ASIC) includes a substrate 801 (e.g., a silicon wafer or silicon die) that includes a FEOL logic layer 890 (e.g., positioned along −Z axis) having active circuitry (e.g., data operations drivers 910-918) electrically coupled with conductive array lines 940 and 945 in a BEOL two-terminal cross-point memory array that is fabricated directly above the substrate 801 (e.g., positioned along +Z axis above upper surface 890s of substrate 801) such that the die 900 is a unitary whole with the active circuitry monolithically fabricated FEOL in the logic layer 890 and one or more of the two-terminal cross-point memory arrays are fabricated BEOL in one or more memory planes (one is shown) that are in contact with one another and in contact with the substrate 801. Here, dielectric material 911 (e.g., SiO₂, SiNₓ, a silicate glass doped or un-doped) is operative to electrically isolate the conductive array lines 940 and 945 and/or memory elements 400 from one another and can also serve as the encapsulation material described above.

FIG. 9B depicts an alternate example of multiple memory planes A, B, C, D, . . . to an nth plane that are in contact with one another and fabricated BEOL directly above the FEOL active circuitry (e.g., data operations drivers 952-966) in logic layer 890 in substrate 801. Dielectric material 955 (e.g., SiO₂ or SiNₓ) is operative to electrically isolate the conductive array lines 940a-940c and 945a-945b and memory elements 400a-400d from one another and can also serve as the encapsulation material described above. In this example, the cross-point arrays include memory elements 400a-400d that share conductive array lines with memory elements in an adjacent memory plane. In another embodiment (not shown), the memory elements in each memory plane are electrically isolated (e.g., using a dielectric material such as SiO₂ or SiNₓ) from the memory elements in adjacent memory planes such that the memory element do not share conductive array lines.

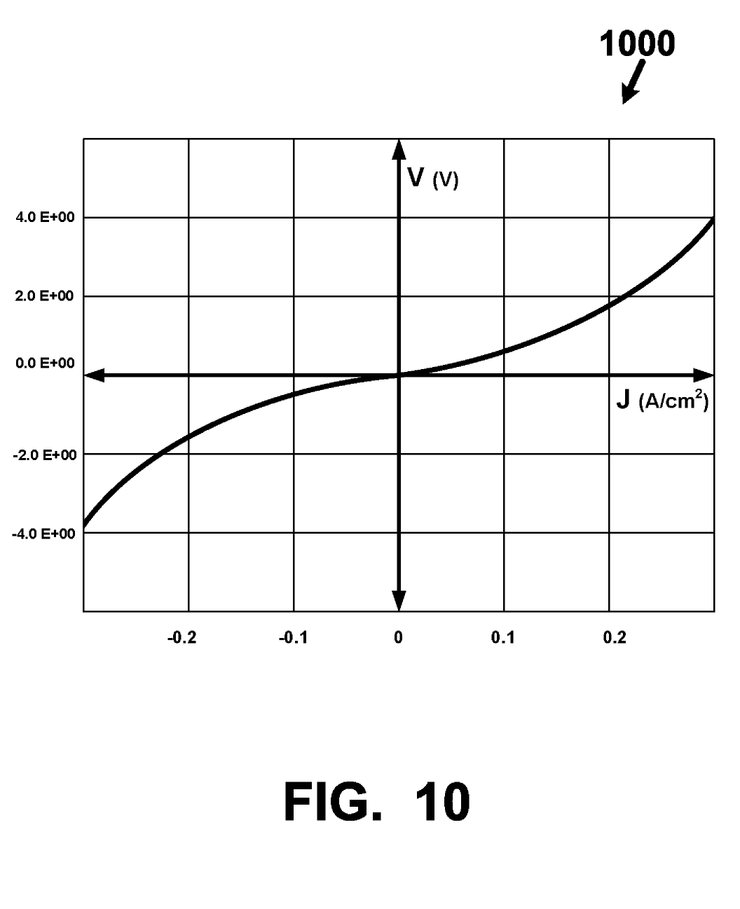

FIG. 10 graphically depicts one example of a non-linear I-V characteristic 1000 for a discrete re-writeable non-volatile two-terminal resistive memory element (e.g., memory element 104, 402, 706) having integral selectivity due to its non-linear I-V characteristics and the non-linear I-V characteristic is maintained regardless of the value of the data stored in the memory cell, that is the I-V characteristic of the memory element does not change from non-linear to linear as a function of the resistive state stored in the memory element. Therefore, the non-linear I-V characteristic of the memory element is non-linear for all values of stored data (e.g., resistive states). Voltage V applied across the memory element is plotted on the Y-axis and current density J through the memory element is plotted on the X-axis. Here, current through the memory element is a non-linear function of the applied voltage across the memory element. Accordingly, when voltages for data operations (e.g., read and write voltages) are applied across the memory element, current flow through the memory element does not significantly increase until after a voltage magnitude of about 2.0V (e.g., at ≈0.2 A/cm²) is reached (e.g., a read voltage of about 2.0V across the memory element). An approximate doubling of the voltage magnitude to about 4.0V does not double the current flow and results in a current flow of ≈0.3 A/cm². The graph depicted is only an example and actual non-linear I-V characteristics will be application dependent and will depend on factors including but not limited to an area of the memory element (e.g., area determines the current density J) and the thin-film materials used in the memory element, just to name a few. The area of the memory element will be application dependent. Here, the non-linear I-V characteristic of the discrete memory element applies to both positive and negative values of applied voltage as depicted by the non-linear I-V curves in the two quadrants of the non-linear I-V characteristic 1000. One advantage of a discrete re-writeable non-volatile two-terminal resistive memory element that has integral selectivity due to a non-linear I-V characteristic is that when the memory element is half-selected (e.g., one-half of the magnitude of a read voltage or a write voltage is applied across the memory element) during a data operation to a selected memory cell(s), the non-linear I-V characteristic is operative as an integral quasi-selection device and current flow through the memory element is reduced compared to a memory cell with a linear I-V characteristic. Therefore, a non-linear I-V characteristic can reduce data disturbs to the value of the resistive state stored in the memory element when the memory element is un-selected or is half-selected. In other embodiments, the memory element (e.g., memory element 104, 402, 706) has a non-linear I-V characteristic for some values of the resistive state stored in the memory element and a linear I-V characteristic for other values of the resistive state stored in the memory element.

FIGS. 11A and 11B are perspective drawings of one example of a CMO-based memory element 1100 that can be used to implement the memory elements (e.g., memory element 104, 402, 706) of the various embodiments of the present invention. FIG. 11A depicts the CMO-based memory element 1100 in an erased state where mobile oxygen ions 1105 that were previously transported from the CMO 1102 into the IMO 1104 are transported 1120 back into the CMO 1102 to change a conductivity profile of the memory element 1100 to the erased state (e.g., a low resistance state). FIG. 11B depicts the CMO-based memory element 1100 in a programmed state where a portion of the mobile ions 1105 in the CMO 1102 are transported 1120 into the IMO 1104 to change the conductivity profile of the memory element to the programmed state (e.g., a high resistance state). The CMO-based memory element 1100 comprises a multi-layered structure that includes at least one CMO layer 1102 that includes mobile oxygen ions 1105. At least one insulating metal oxide (IMO) layer 1104 that is in contact with the at least one CMO layer 1102. The CMO layer 1102 is electrically coupled with a bottom electrode 1106 and the IMO layer 1104 is electrically coupled with a top electrode 1108 such that the CMO layer 1102 and IMO layer 1104 are electrically in series with each other and with the top and bottom electrodes 1108 and 1106. The bottom electrode 1106 can be formed on electrically conductive support layer 1125 as described above. For example, the bottom electrode 1106 is electrically coupled with one of the WLs 1114 of a memory array and the top electrode 1108 is electrically coupled with one of the BLs 1110 of the memory array (e.g., a two-terminal cross-point memory array). The positions of the CMO and IMO layers in the memory element 1100 can be flipped (not shown, but see FIGS. 1, 4, and 8) such that the IMO 1104 is formed above and in contact with the BE 1106 and the CMO 1102 is positioned above and in contact with the IMO 1104 and the CMO 1102 is electrically coupled with the TE 1108. Here, in the flipped configuration, the BE 1106 can be formed on support layer 1125 as described above.

The CMO layer 1102 comprises an ionic conductor that is electrically conductive and includes mobile oxygen ions 1105. The material for the CMO layer 1102 can have an amorphous structure, a crystalline structure (e.g., single crystalline or polycrystalline), or both, and the crystalline structure does not change due to data operations on the memory element 1100. For example, read and write operations to the memory element 1100 do not alter the crystalline structure of the CMO layer 1102. In other embodiments, the CMO layer 1102 can have an amorphous structure or a blended structure that is a combination of amorphous and crystalline. In either case, the structure is not changed by data operations on the memory element 1100. As described above, the CMO layer 1102 can comprise one or more layers of a CMO material.

The IMO layer 1104 comprises one or more layers of a high-k dielectric material having a substantially uniform thickness (e.g., a combined thickness when multiple layers are used) that is approximately less than 50 Angstroms. IMO layer 1104 is also an ionic conductor that is electrically insulating. The IMO layer 1104 is operative as a tunnel barrier (e.g., trap assisted tunneling, direct tunneling, Fowler-Nordheim tunneling, Frenkel-Poole tunneling, etc.) that is configured for electron tunneling during data operations to the memory element 1100 and as an electrolyte to the mobile oxygen ions 1105 and is permeable to the mobile oxygen ions 1105 during write operations to the memory element 1100 such that during write operations oxygen ions 1105 are transported 1120 between the CMO and IMO layers 1102 and 1104.

In various embodiments, in regards to the layers 1102 and 1104 of FIGS. 11A-D, the CMO layer 1102 can include one or more layers of a conductive metal oxide material, such as one or more layers of a conductive metal oxide-based (“CMO-based”) material, for example. The CMO material is selected for it properties as a variable resistive material that includes mobile oxygen ions and is not selected based on any ferroelectric properties, piezoelectric properties, magnetic properties, superconductive properties, or for any mobile metal ion properties. In various embodiments, layer 1102 can include but is not limited to a manganite material, a perovskite material selected from one or more the following: PrCaMnOₓ (PCMO), LaNiOₓ (LNO), SrRuOₓ (SRO), LaSrCrOₓ (LSCrO), LaCaMnOₓ (LCMO), LaSrCaMnOₓ (LSCMO), LaSrMnOₓ (LSMO), LaSrCoOₓ (LSCoO), and LaSrFeOₓ (LSFeO), where x is nominally 3 for perovskites (e.g., x≦3 for perovskites) or structure 1102 can be a conductive binary metal oxide structure comprised of a conductive binary metal oxide having the form AₓO_{y}, where A represents a metal and O represents oxygen. The conductive binary oxide material may optionally be doped (e.g., with niobium Nb, fluorine F, and/or nitrogen N) to obtain the desired conductive properties for a CMO.

In various embodiments, IMO layer 1104 can include but is not limited to a material for implementing a tunnel barrier layer and is also an electrolyte that is permeable to the mobile oxygen ions 1105 at voltages for write operations. Suitable materials for the layer 1104 include but are not limited to one or more of the following: high-k dielectric materials, rare earth oxides, rare earth metal oxides, yttria-stabilized zirconium (YSZ), zirconia (ZrOₓ), zirconium oxygen nitride (ZrOxNy), yttrium oxide (YOₓ), erbium oxide (ErOₓ), gadolinium oxide (GdOₓ), lanthanum aluminum oxide (LaAlOₓ), hafnium oxide (HfOₓ), aluminum oxide (AlOx), silicon oxide (SiOx), cerium oxide (CeOₓ), and equivalent materials. Typically, the layer 1104 comprises a thin film layer having a substantially uniform thickness of approximately less than 50 Angstroms (e.g., in a range from about 5 Angstroms to about 35 Angstroms). When multiple IMO layers 1104 are implemented a combined thickness of all the layers is less than 50 Angstroms (e.g., in a range from about 15 Angstroms to about 40 Angstroms). Although the foregoing description has focused on a CMO layer that includes mobile oxygen ions, the present invention is not limited to a memory material (e.g., the CMO) having mobile oxygen ions and the memory element may be implemented with memory material(s) having other ion species such as metal ions and the ions may be cations (+ charge) or anions (− charge). Moreover, the support layer described herein is operable for other types of memory devices that do not use the memory materials described herein (e.g., CMO and IMO), but nevertheless require or otherwise need smooth and planar structures upon which to form one or more thin-film layers of memory material for a memory device(s). For example, other types of memory devices, whether volatile, non-volatile, one-time-programmable (OTP), such as conductive bridge memory (CBRAM), interfacial memory, ferroelectric memory, Memristor and/or Memristive memory, phase change memory (PCRAM), filamentary memory, carbon nano-tube memory, fuse based memory, anti-fuse based memory, mono-layer memory, bi-layer memory, tri-layer memory, various types of MRAM (e.g., ferromagnetic memory), various types of RRAM, or the like may benefit from a support layer having a substantially smooth and planar upper surface upon which to deposit or otherwise form one or more layers of material for a memory device. The support layer can promote lower surface roughness and planar surfaces and/or provide for grain and/or lattice match between the support layer and the layer deposited on the support layer. The support layer can be used to improve surface morphology of the layer deposited on it and/or on subsequent layers of material as they are formed or otherwise deposited.

When in an erased state, as depicted in FIG. 11A, mobile oxygen ions 1105 (denoted by the small black-filled circles in FIGS. 11A-D) are concentrated in the CMO layer 1102 and the CMO-based memory element 1100 exhibits a low resistance to current (e.g., is in a low-resistance state). For example, the CMO-based memory element 1100 is programmed to a programmed state (FIG. 11B) by applying a positive voltage potential to the top electrode 1108 and a negative voltage potential (e.g., or a less positive voltage potential) to the bottom electrode 1106. The applied voltage creates an electric field E2 within the layers 1102 and 1104 that transports 1120 the oxygen ions 1105 from the CMO layer 1102 into the IMO layer 1104, causing the CMO-based memory element 1100 to conform to a high resistance, programmed state. When an erase voltage of reverse polarity is applied across the top and bottom electrodes 1108 and 1106, the mobile oxygen ions 1105 are transported 1120 back into the CMO layer 1102 (FIG. 11A) in response to electric field E1, returning the CMO-based memory element 1100 to a low-resistance, erased state. Writing data to the memory element 1102 does not require a prior erase operation and once data is written to the memory element 1100, the data is retained in the absence of electrical power. Although erase and program voltages have been described as examples of a write operation, writing data to the memory element 1100 requires application of write voltage potentials having an appropriate magnitude and polarity to the terminals of the memory element 1100 (e.g., applied to WL 1114 and BL 1110 of a selected memory element(s)). In FIGS. 11C and 11D, reading data stored in the memory element 1100 requires application of read voltage potentials having an appropriate magnitude and polarity to the terminals of the memory element 1100 (e.g., applied to WL 1114 and BL 1110 of a selected memory element(s)). The read voltage is operative to generate a read current I_{READ} that flows through the memory element 1100 while the read voltage is applied. The magnitude of the read voltage and the resistive value of the data stored in the selected memory element 1100 determine the magnitude of the read current I_{READ}. In FIG. 11C, the memory element 1100 is depicted in the erased state (e.g., low resistance state) and in FIG. 11D the memory element 1100 is depicted in the programmed state (e.g., high resistance state). Therefore, given the same magnitude of read voltage (e.g., 1.5V), the read current I_{READ1} will have a higher magnitude (e.g., due to the lower resistance state) depicted in FIG. 11C than the read current I_{READ2} depicted in FIG. 11D due to the higher resistance of the programmed state (i.e., I_{READ1}>I_{READ2}). Application of the read voltage does not cause mobile oxygen ion 1105 transport 1120 because the magnitude of the read voltage is less than the magnitude of the write voltage and therefore the read voltage does not generate an electric field having sufficient magnitude to cause mobile oxygen ion 1105 transport 1120 during read operations. Therefore, it is not necessary to re-write the data stored in the memory element 1100 after a read operation because the read operation is non-destructive to the stored data (e.g., does not corrupt or significantly disturb the stored data).

Once the CMO-based memory element 1100 is programmed or erased to either state, the memory element 1100 maintains that state even in the absence of electrical power. In other words, the CMO-based memory element 1100 is a non-volatile memory element. Therefore, no battery backup or other power source, such as a capacitor or the like, is required to retain stored data. The two resistive states are used to represent two non-volatile memory states, e.g., logic “0” and logic “1.” In addition to being non-volatile, the CMO-based memory element 1100 is re-writable since it can be programmed and erased over and over again. These advantages along with the advantage of being able to stack the two-terminal CMO-based memory elements in one or more memory layers above FEOL semiconductor process layers, are some of the advantages that make the CMO-based memory arrays of the present invention a viable and competitive alternative to other non-volatile memory technologies such as Flash memory. In other embodiments, the memory element 1100 stores two or more bits of non-volatile data (e.g., MLC) that are representative of more than two logic states such as: “00”; “01”; “10”; and “11”, for example. Those logic states can represent a hard-programmed state “00”, a soft-programmed state “01”, a soft-erased state “10”, and a hard-erased state “11”, and their associated conductivity values (e.g., resistive states). Different magnitudes and polarities of the write voltage applied in one or more pulses that can have varying pulse shapes and durations can be used to perform write operations on the memory element 1100 configured for SLC and/or MLC.

FIG. 11E is a top plan view depicting a single wafer (denoted as 1170 and 1170′) at two different stages of fabrication on the same wafer: FEOL processing on the wafer denoted as 1170 during the FEOL stage of microelectronics processing where active circuitry (e.g., CMOS circuitry) in logic layer 890 is fabricated on the substrate that comprises base layer die 801 (e.g., a silicon wafer); followed by BEOL processing on the same wafer denoted as 1170′ during the BEOL stage of microelectronics processing where one or more layers (e.g., 1151 or 1150) of BEOL non-volatile memory are fabricated directly on top of the FEOL logic layer 890 (not shown) (e.g., on an upper surface 890s of the FEOL interlayer interconnect structure). The single layer 1151 or multiple vertically stacked layers 1150 are not glued, soldered, wafer bonded, or otherwise physically or electrically connected with the base layer die 801, instead they are grown directly on top of the base layer die 801 so that they are integrally connected with the base layer die 801 and with one another, are electrically coupled with the circuitry in the FEOL logic layer 890, thereby forming a unitary integrated circuit die 1199 that includes monolithically integrated FEOL and BEOL portions (e.g., inseparable FEOL circuitry and BEOL memory portions). Wafer 1170 includes a plurality of the base layer die 801 formed individually on wafer 1170 as part of the FEOL process. As part of the FEOL processing, the base layer die 801 may be tested 1172 to determine their electrical characteristics, functionality, yield, performance grading, etc. After all FEOL processes have been completed, the wafer 1170 is optionally transported 1104 for subsequent BEOL processing (e.g., adding one or more layers of memory such as single layer 1151 or multiple layers 1150) directly on top of each base layer die 801. A base layer die 801 is depicted in cross-sectional view along a dashed line FF-FF where a substrate (e.g., a silicon Si wafer) for the die 801 and its associated active circuitry in logic layer 890 have been previously fabricated FEOL and are positioned along the −Z axis. For example, the one or more layers of memory (e.g., 1151 or 1150) are grown directly on top of an upper surface 890s of each base layer die 801 as part of the subsequent BEOL processing. Upper layer 890s can be an upper planar surface of the aforementioned interlayer interconnect structure operative as a foundation for subsequent BEOL fabrication of the memory layers along the +Z axis.

During BEOL processing the wafer 1170 is denoted as wafer 1170′, which is the same wafer subjected to additional processing to fabricate the memory layer(s) and their associated memory elements directly on top of the base layer die 801. Base layer die 801 that failed testing may be identified either visually (e.g., by marking) or electronically (e.g., in a file, database, email, etc.) and communicated to the BEOL fabricator and/or fabrication facility. Similarly, performance graded base layer die 801 (e.g., graded as to frequency of operation) may identified and communicated to BEOL the fabricator and/or fabrication facility. In some applications the FEOL and BEOL processing can be implemented by the same fabricator or performed at the same fabrication facility. Accordingly, the transport 1104 may not be necessary and the wafer 1170 can continue to be processed as the wafer 1170′. The BEOL process forms the aforementioned memory elements and memory layer(s) directly on top of the base layer die 801 to form a finished die 1199 that includes the FEOL circuitry portion 890 along the −Z axis and the BEOL memory portion along the +Z axis. For example, the memory elements (e.g., memory elements 104, 402, 706) and their associated conductive array lines (e.g., WLs and BLs) can be fabricated during the BEOL processing. The types of memory elements that can be fabricated BEOL are not limited to those described herein and the materials for the memory elements are not limited to the memory element materials described herein. A cross-sectional view along a dashed line BB-BB depicts a memory device die 1199 with a single layer of memory 1151 grown (e.g., fabricated) directly on top of base die 1106 along the +Z axis, and alternatively, another memory device die 1199 with three vertically stacked layers of memory 1150 grown (e.g., fabricated) directly on top of base die 1106 along the +Z. Finished die 1199 on wafer 1170′ may be tested 1174 and good and/or bad die identified. Subsequently, the wafer 1170′ can be singulated 1178 to remove die 1199 (e.g., die 1199 are precision cut or sawed from wafer 1170′) to form individual memory device die 1199. The singulated die 1199 may subsequently be packaged 1179 to form an integrated circuit chip 1190 for mounting to a PC board or the like, as a component in an electrical system (not shown) that electrically accesses IC 1190 to perform data operations on BEOL memory. Here a package 1181 can include an interconnect structure 1187 (e.g., pins, solder balls, or solder bumps) and the die 1199 mounted in the package 1181 and electrically coupled 1183 with the interconnect structure 1187 (e.g., using wire bonding or soldering). The integrated circuits 1190 (IC 1190 hereinafter) may undergo additional testing 1185 to ensure functionality and yield. The die 1199 or the IC 1190 can be used in any system requiring non-volatile memory and can be used to emulate a variety of memory types including but not limited to SRAM, DRAM, ROM, and Flash. Unlike conventional Flash non-volatile memory, the die 1199 and/or the ICs 1190 do not require an erase operation or a block erase operation prior to a write operation so the latency associated with conventional Flash memory erase operations is eliminated and the latency associated with Flash OS and/or Flash file system required for managing the erase operation is eliminated. Random access data operations to the die 1199 and/or the ICs 1190 can be implemented with a granularity of 1-bit (e.g., a single memory element) or more (e.g., a page or block of memory elements). Moreover, a battery back-up power source or other AC or DC power source is not required to retain data stored in the memory elements embedded in each memory layer (1151 or 1150) because the memory is non-volatile and retains stored data in the absence of electrical power. Another application for the ICs 1190 is as a replacement for conventional Flash-based non-volatile memory in embedded memory, solid state drives (SSDs), hard disc drives (HDDs), or cache memory, for example.

In some applications it may be desirable to deposit thin-film layers of material that form a selection device or a non-ohmic device (NOD). Selection devices such as one or more diodes (e.g., 1D-1R, 2D-1R), transistors (e.g., 1T-1R, 2T-1R), or NODs such as MIM or MIIM devices have advantages and disadvantages. Advantages include improving half-select ratio for un-selected memory cells during data operations, reduction or elimination of disturbs to un-selected or half-selected memory cells, and reduction of leakage currents for half-selected memory cells, just to name a few. On the other hand, disadvantages include additional processing steps, additional mask sets and their associated costs, reduced device yield due to the additional processing steps, and higher manufacturing costs, just to name a few. Further, a memory cell that includes a selection device or NOD electrically in series with the memory element will have a voltage drop across the selection device/NOD and the memory element during data operations. The voltage drop across terminals of the memory cell must therefore be increased to account for the voltage drop across the selection device/NOD so that the voltage drop across the memory element is sufficient to read or write the memory element. Higher voltages increase power consumption and waste heat generation (power dissipation).

To that end, the memory element can optionally be electrically coupled with a selection device/NOD. The selection device/NOD can be of the type described in U.S. patent application Ser. No. 11/881,473, filed Jul. 26, 2007, now U.S. Pat. No. 7,995,371, and entitled “Threshold Device For A Memory Array”; and U.S. Pat. No. 7,884,349, issued on Feb. 8, 2011, and entitled “Selection Device for Re-Writable Memory” both of which have already been incorporated herein by reference in their entirety.

The various embodiments of the invention can be implemented in numerous ways, including as a system, a process, an apparatus, or a series of program instructions on a computer readable medium such as a computer readable storage medium or a computer network where the program instructions are sent over optical or electronic communication links. In general, the steps of disclosed processes can be performed in an arbitrary order, unless otherwise provided in the claims.

The foregoing description, for purposes of explanation, uses specific nomenclature to provide a thorough understanding of the invention. However, it will be apparent to one skilled in the art that specific details are not required in order to practice the invention. In fact, this description should not be read to limit any feature or aspect of the present invention to any embodiment; rather features and aspects of one embodiment can readily be interchanged with other embodiments. Notably, not every benefit described herein need be realized by each embodiment of the present invention; rather any specific embodiment can provide one or more of the advantages discussed above. In the claims, elements and/or operations do not imply any particular order of operation, unless explicitly stated in the claims. It is intended that the following claims and their equivalents define the scope of the invention.

What is claimed is:

1. A memory cell, comprising:
a support layer including a substantially smooth and planar upper surface;
a first electrode in contact with the support layer, the support layer configured to influence formation of the first electrode and to determine a substantially smooth first surface of the first electrode;
a two-terminal re-writeable non-volatile memory element in contact with the first surface, the memory element including at least one layer of insulating metal oxide (IMO) that is permeable to mobile ions during write operations to the memory element; and
a second electrode in contact with the memory element, the memory element electrically in series with the first and second electrodes, and
the first surface of the first electrode operatively facilitates uniform current densities through unit cross-sectional areas of the at least one layer of IMO.

2. The memory cell of claim 1, wherein the first surface comprises a plurality of surface portions of the first electrode aligned in a common plane.

3. The memory cell of claim 1, wherein the support layer is configured to align top surfaces of units of a material constituting the first electrode to establish a surface roughness value for the at least one layer of IMO, the surface roughness value being set below a threshold value of surface roughness.

4. The memory cell of claim 3, wherein the threshold value of surface roughness is less than or equal to about 6 Angstroms.

5. The memory cell of claim 4, wherein the threshold value of surface roughness represents a root-mean-square (RMS) value of the surface roughness value.

6. The memory cell of claim 1, wherein the first surface is configured to establish a uniform thickness of the at least one layer of IMO.

7. The memory cell of claim 6, wherein the uniform thickness of the at least one layer of IMO varies by no more than about 0.5 to about 1.5 Angstroms from a plane passing through the at least one layer of IMO, the plane being oriented perpendicular to a current flow in the memory element.

8. The memory cell of claim 1, wherein the support layer includes a lattice structure operative to influence alignment of top surfaces of units of a material that form the first electrode and the top surfaces are coplanar with one another.

9. The memory cell of claim 8, wherein the first electrode comprises either platinum and the units of the material comprise grains of platinum or comprises another noble metal and the units of the material comprise grains of the another noble metal.

10. The memory cell of claim 9, wherein the top surfaces of neighboring grains of platinum vary less than about 8 Angstroms.

11. The memory cell of claim 1, wherein the support layer comprises an electrically conductive material.

12. The memory cell of claim 1, wherein the first electrode, the support layer or both comprise a planarized layer of material.

13. The memory cell of claim 1, wherein the memory element further includes at least one layer of conductive metal oxide (CMO) including mobile oxygen ions.

14. The memory cell of claim 13, wherein the least one layer of CMO comprises a planarized layer of material.

15. The memory cell of claim 13, wherein the least one layer of CMO comprises a material that is deposited in whole or in part using atomic layer deposition (ALD).

16. The memory cell of claim 1, wherein a selected one or both of the support layer or the at least one layer of IMO comprises an atomic layer deposition (ALD) deposited material.

17. The memory cell of claim 1, wherein the support layer includes a lattice structure operative to influence alignment of top surfaces of units of a layer of material formed on the substantially smooth first surface of the first electrode, and the top surfaces are coplanar with one another.

18. The memory cell of claim 17, wherein the layer of material comprises the at least one layer of IMO.

19. The memory cell of claim 17, wherein the layer of material comprises at least one layer of a conductive metal oxide (CMO) including mobile oxygen ions.

20. The memory cell of claim 1, wherein the mobile ions comprise mobile oxygen ions.

21. An integrated circuit, comprising:
a semiconductor substrate;
a logic layer including active circuitry fabricated front-end-of-the-line (FEOL) on the semiconductor substrate;
a two-terminal cross-point memory array vertically fabricated back-end-of-the-line (BEOL) directly above and in direct contact with semiconductor substrate, the two-terminal cross-point memory array including
a plurality of X-line conductive array lines, a plurality of Y-line conductive array lines arranged orthogonally to the plurality of X-line conductive array lines, the plurality of X-line and Y-line conductive array lines electrically coupled with at least a portion of the active circuitry,
a plurality of re-writeable non-volatile two-terminal discrete memory elements, each memory element disposed between and electrically in series with a unique pair of one of the X-line conductive array lines and one of the Y-line conductive array lines, each memory element including a first electrode in contact with a first portion of the memory element and a second electrode in contact with a second portion of the memory element, and
a support layer included in each memory element and having a substantially smooth and planar surface upon which the first electrode or the second electrode is formed, the support layer including a crystalline orientation configured to promote formation of metal grains in a specific orientation for the first electrode or the second electrode, the specific orientation operative to facilitate formation of top surfaces of the metal grains in or parallel to a common plane.

22. The integrated circuit of claim 21, wherein the first electrode, the second electrode, or both comprises platinum or another noble metal.

23. The integrated circuit of claim 21, wherein the first electrode, the second electrode, or both include a planarized upper surface.

24. The integrated circuit of claim 21, wherein the support layer comprises a planarized support layer.

25. The integrated circuit of claim 21, wherein the support layer comprises an electrically conductive material and the support layer is electrically in series with the memory element and its respective first and second electrodes

26. The integrated circuit of claim 21, wherein each memory element includes at least one layer of insulating metal oxide (IMO) that is permeable to mobile ions during write operations to the memory element.

27. The integrated circuit of claim 26, wherein a selected one or both of the support layer or the at least one layer of IMO comprises an atomic layer deposition (ALD) deposited material.

28. The memory cell of claim 22, wherein each memory element includes at least one layer of conductive metal oxide (CMO) including mobile oxygen ions.

29. The integrated circuit of claim 28, wherein the at least one layer of the CMO material comprises a planarized CMO material.

30. The integrated circuit of claim 28, wherein the least one layer of CMO comprises a material that is deposited in whole or in part using atomic layer deposition (ALD).

31. The integrated circuit of claim 21, wherein the plurality of memory elements comprises two neighboring memory elements and support layers of the two neighboring memory elements are operative to maintain a difference of about 50% or less between magnitudes of current flowing through the two neighboring memory elements during data operations.

32. A method of forming two-terminal re-writeable non-volatile resistive memory elements in a two-terminal cross-point array, comprising:
forming a support layer having a substantially smooth and planar upper surface and similarly-oriented crystalline structures;
depositing an electrode upon the substantially smooth and planar upper surface of the support layer, the crystalline structures configured to facilitate growth of metal grains in the electrode, the electrode including a substantially smooth and planar first surface; and
fabricating at least one layer of insulating metal oxide (IMO) on the substantially smooth and planar first surface of the electrode to form a substantially smooth interface between the electrode and the at least one layer of IMO.

33. The method of claim 32, wherein fabricating the at least one layer of IMO on the substantially smooth and planar first surface of the electrode to form the substantially smooth interface comprises forming a second surface of the at least one layer of IMO with an RMS surface roughness less than or equal to about 6 Angstroms.

34. The method of claim 32 and further comprising:
planarizing the electrode to form the substantially smooth and planar first surface.

35. The method of claim 32 and further comprising:
planarizing the support layer to form the substantially smooth and planar upper surface.

36. The method of claim 32, wherein the fabricating includes depositing a selected one or both of the support layer or the at least one layer of IMO using an atomic layer deposition (ALD) process.

37. The method of claim 32 and further comprising:
fabricating at least one layer of conductive metal oxide (CMO) on an upper surface of the at least one layer of IMO.

38. The method of claim 37, wherein the fabricating the at least one layer of CMO includes depositing in whole or in part the at least one layer of the CMO using an atomic layer deposition (ALD) process.
